(19) United States
(12) Patent Application Publication
(10) Pub. No.: US 2025/0336896 A1
(43) Pub. Date: Oct. 30, 2025

(54) PACKAGED ELECTRONIC DEVICE COMPRISING CIRCUITS FORMED BY A PLURALITY OF POWER DEVICES COUPLED IN SOURCE-TO-SOURCE OR DRAIN-TO-DRAIN CONFIGURATION

(71) Applicant: STMicroelectronics International N.V., Geneva (CH)

(72) Inventors: Cristiano Gianluca STELLA, San Gregorio Di Catania (IT); Francesco SALAMONE, Acireale (IT); Dario CUCUCCIO, Catania (IT)

(73) Assignee: STMicroelectronics International N.V., Geneva (CH)

(21) Appl. No.: 19/174,126

(22) Filed: Apr. 9, 2025

(30) Foreign Application Priority Data
Apr. 24, 2024 (IT) 102024000009481

(51) Int. Cl. H01L 25/07; H01L 23/00; H01L 23/498; H01L 23/538

(52) U.S. Cl. CPC H01L 25/072; H01L 23/49811; H01L 23/5386; H01L 24/08; H01L 2224/08225; H01L 2924/13055; H01L 2924/13091

(57) ABSTRACT

Electronic device having a first substrate element; a second substrate element; and a plurality of dice of semiconductor material integrating respective power devices and forming circuits having a separate terminal, a common terminal and an intermediate terminal, wherein the power devices are coupled in a same back-to-back configuration at the intermediate terminal. The first substrate element has a conductive layer patterned to form a first separate contact island coupled to the separate terminal of a first circuit; a second separate contact island coupled to the separate terminal of the second circuit; a common contact island coupled to the common terminal of the first and the second circuits. The second substrate element has a conductive layer patterned to form a first intermediate contact island coupled to the intermediate terminal of the first circuit, and a second intermediate contact island coupled to the intermediate terminal of the second circuit.

### BACKGROUND

### Technical Field

The present disclosure relates to a packaged electronic device comprising circuits formed by a plurality of power devices coupled in a source-to-source configuration (i.e., with coupled source regions) or drain-to-drain configuration (i.e., with coupled drain regions).

For example, the circuit may comprise power devices operating at high voltage (even 1000-2000 V) with currents which may rapidly switch, such as devices based on silicon carbide or silicon, such as superjunction MOSFETs and IGBTs, and devices based on gallium nitride (GaN) and similar.

### Description of the Related Art

As is known, for power electronic circuits and devices of the type indicated above, packages capable of providing high heat loss are desired. These packages are usually formed by rigid insulating bodies, for example of resin, generally of a parallelepiped shape, embedding the electronic component or components integrated in respective dice.

The packages may comprise a dissipation structure in contact with the electronic component(s).

In this case, the dissipation structure faces at least one main surface of the package and generally takes up a good part of this surface. The dissipation structure is sometimes formed by the same metal support (referred to as “leadframe”) which supports the die or dice integrating one or more electronic components and a plurality of leads for the external connection. In general, in this case, the leadframe has a surface directly facing the outside of the package.

For example, in case of a packaged device comprising a silicon MOSFET transistor, the die integrating the MOSFET transistor may have a drain pad on one first main surface thereof and at least two pads (respectively, a source pad and a gate pad) on a second main surface, opposite to the first one. A transistor pad (typically the drain pad) is attached to the support portion of the leadframe, which is in direct contact with one or more leads. The other pads (typically, the gate and source pads) are bonded to the other leads by bonding wires or clips. This standard package normally envisages the arrangement of the leads on the same side of the dissipation structure and therefore normally allows downward dissipation.

Other devices, for example those comprising GaN, have a different external contact arrangement, with a conductive rear surface (forming a source contact) and front pads for the other terminals. The source terminal is also often arranged also on the front side.

To obtain increasingly compact dimensions, horizontal packages have been developed for these power devices, for example of the Surface Mounting Device (SMD) type, which also allow Dual Side Cooling (DSC).

For example, Italian patent 102022000006563 (corresponding to publications EP 4 273 925A1 and US 2023/0317685) describes a package for bridge circuit branches comprising series-arranged transistors, with the source terminal of the high-side device coupled to the drain terminal of the low-side device.

In particular, in the aforementioned Italian patent 102022000006563, the dice integrating the power transistors are mutually coupled through conductive regions and islands formed in two DBC-Direct Bonded Copper-substrates which sandwich the same dice and whose conductive layers facing the dice are suitably patterned.

This solution has proven to be very advantageous thanks to its high compactness, high dissipation, case of use in more complex circuits, reduced parasitic effects, and reliability.

It is therefore desirable to provide integrated devices having similar packages capable of implementing other circuit topologies including power devices coupled in back-to-back configuration and specifically in source-to-source or drain-to-drain configuration.

### BRIEF SUMMARY

According to the present disclosure, a packaged electronic device is provided.

### BRIEF DESCRIPTION OF THE SEVERAL VIEWS OF THE DRAWINGS

For a better understanding of the present disclosure, some embodiments are now described, purely by way of non-limiting example, with reference to the attached drawings, wherein:

FIG. 1 shows a simplified diagram of an energy conversion unit usable for charging electric storage elements and/or accumulating energy and using power devices in a back-to-back configuration;

FIG. 2 is a simplified cross-section of a MOSFET transistor formed in a die based on silicon or silicon carbide (SiC) and usable in the energy conversion unit of FIG. 1;

FIG. 3 is a simplified cross-section of another MOSFET transistor formed in a die provided in a die based on gallium nitride (GaN) and usable in the energy conversion unit of FIG. 1;

FIG. 4A is a schematic representation of an embodiment of the present packaged electronic device, showing the mutual arrangement of components and some connection regions;

FIG. 4B is a perspective top view of an upper portion of the electronic device of FIG. 4A, before coupling with a lower portion and packaging;

FIG. 4C is a perspective top view of a lower portion of the electronic device of FIG. 4A, before coupling with the upper portion and packaging;

FIG. 4D is a perspective top view of the electronic device of FIGS. 4A-4C, with the upper portion overlying the lower portion and in ghost;

FIG. 5 is a perspective top view of the electronic device of FIGS. 4A-4C, after the mutual coupling of the upper part and the lower part and after packaging;

FIG. 6A is a schematic representation of another embodiment of the present packaged electronic device, showing the mutual arrangement of components and some connection regions;

FIG. 6B is a perspective top view of an upper portion of the electronic device of FIG. 6A, before coupling with a lower portion and packaging;

FIG. 6C is a perspective top view of a lower portion of the electronic device of FIG. 6A, before coupling with the upper portion and packaging;

FIG. 6D is a perspective top view of the electronic device of FIGS. 6A-6C, with the upper portion overlying the lower portion and in ghost;

FIG. 7 shows a variant of the coupling arrangement shown in FIG. 4;

FIG. 8A is a schematic representation of another embodiment of the present packaged electronic device, showing the mutual arrangement of components and some connection regions;

FIG. 8B is a perspective top view of an upper portion of the electronic device of FIG. 8A, before coupling with a lower portion and packaging;

FIG. 8C is a perspective top view of a lower portion of the electronic device of FIG. 8A, before coupling with the upper portion and packaging;

FIG. 8D is a perspective top view of the electronic device of FIGS. 8A-8C, with the upper portion overlying the lower portion and in ghost;

FIG. 9A is a schematic representation of another embodiment of the present packaged electronic device, showing the mutual arrangement of components and some connection regions;

FIG. 9B is a perspective top view of an upper portion of the electronic device of FIG. 9A, before coupling with a lower portion and packaging;

FIG. 9C is a perspective top view of a lower portion of the electronic device of FIG. 9A, before coupling with the upper portion and packaging;

FIG. 9D is a perspective top view of the electronic device of FIGS. 9A-9C, with the upper portion overlying the lower portion and in ghost;

FIG. 10 is a block diagram of a power converter circuit using the present electronic device;

FIG. 11 shows a simplified diagram of another energy conversion unit usable for charging electric storage elements and/or accumulating energy and using power devices in a back-to-back configuration;

FIG. 12A is a schematic representation of the present packaged electronic device usable in the energy conversion unit of FIG. 11, showing the mutual arrangement of components and some connection regions, according to an embodiment;

FIG. 12B is a perspective view of an upper portion of the electronic device of FIG. 12A, before coupling with a lower portion and packaging;

FIG. 12C is a perspective top view of a lower portion of the electronic device of FIG. 12A, before coupling with the upper portion and packaging;

FIG. 12D is a perspective top view of the electronic device of FIGS. 12A-12C, with the upper portion overlying the lower portion and in ghost;

FIG. 13A is a schematic representation of present packaged electronic device usable in the energy conversion unit of FIG. 11, showing the mutual arrangement of components and some connection regions, according to a further embodiment;

FIG. 13B is a perspective view of an upper portion of the electronic device of FIG. 2A, before coupling with a lower portion and packaging;

FIG. 13C is a perspective top view of a lower portion of the electronic device of FIG. 13A, before coupling with the upper portion and packaging; and

FIG. 13D is a perspective top view of the electronic device of FIGS. 13A-13C, with the upper portion overlying the lower portion and in ghost.

### DETAILED DESCRIPTION

The following description refers to the arrangement shown; consequently, expressions such as “above,” “below,” “upper,” “lower,” “right,” “left” relate to the attached Figures and are not to be interpreted in a limiting manner.

As used herein, the terms “connected” and “coupled” are intended to be interpreted with the broadest possible meaning. Specifically, the phrase “A is connected to B” encompasses both a direct connection between A and B—where no intervening components or elements are present—as well as an indirect connection, where one or more intervening components or elements exist between A and B. Similarly, the term “coupled” should be understood in the same manner. For instance, “A is coupled to B” includes both a direct physical or electrical coupling and an indirect coupling facilitated through one or more intermediate components or elements. Unless expressly specified otherwise (e.g., “directly connected”), these terms do not imply or require direct physical contact.

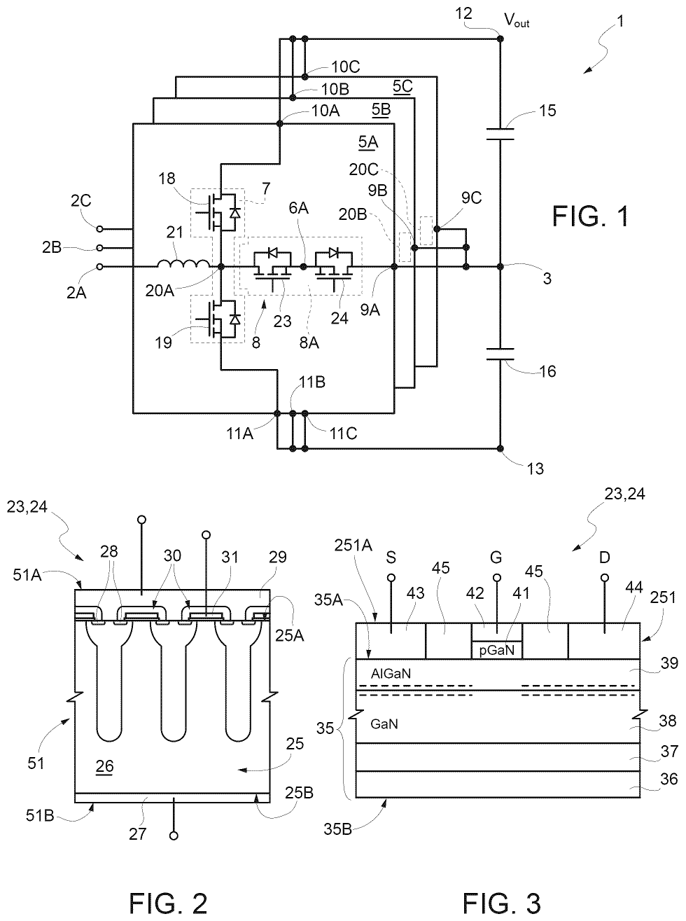

FIG. 1 shows a simplified diagram of an energy conversion unit 1 for AC-DC or DC-AC conversion, usable for example in bidirectional AC-DC electric vehicle (EV) charging stations, in bidirectional AC-DC on-board charging (OBD) systems and in bidirectional AC-DC power converters for accumulating domestic energy.

However, the energy conversion unit 1 is also usable in unidirectional charging systems.

The energy conversion unit 1 has three first connection nodes 2A-2C, each configured to be coupled to a respective phase of a three-phase voltage, for example an input voltage supplied by the mains or an output voltage, for example of an energy generation system such as a photovoltaic system.

The energy conversion unit 1 also has a second connection node 3, configured to be coupled to a DC electrical device, for example a user such as a motor or other electrical device, a storage element/battery, or a DC input power supply, possibly through a drive circuit not shown.

The energy conversion unit 1 of FIG. 1 comprises three sub-circuits 5A, 5B, 5C.

Each sub-circuit 5A, 5B, 5C is coupled to a respective first connection node 2A-2C and has a respective third connection node 9A-9C, a respective fourth connection node 10A-10C and a respective fifth connection node 11A-11C.

The third connection nodes 9A-9C are coupled to each other and to the second connection node 3; the fourth connection nodes 10A-10C are coupled to each other and to a first external node 12, and the fifth connection nodes 11A-11C are coupled to each other and to a second external node 13. A voltage, for example an output voltage Vout, is present (in use), between the first and the second external nodes 12, 13, when the energy conversion unit 1 operates as an AC-DC converter.

A first and a second capacitor 15, 16 are coupled in series between the first and the second external nodes 12, 13 and have a common node forming the second connection node 3. In other words, the first capacitor 15 is coupled between the first external node 12 and the second connection node 3; the second capacitor 16 is coupled between the second connection node 3 and the second external node 13. In FIG. 1, therefore, the output voltage Vout is applied across capacitors 15, 16.

In a manner not shown, further circuits, for example a DC-DC converter and a secondary rectifier circuit, may be connected to the second connection node 3 and to the external nodes 12, 13, in cascade to the energy conversion unit 1, to output a high direct voltage, for example variable between 400 and 800 V.

However, the energy conversion unit 1 may be coupled with the outside through different circuits, depending on the system it is inserted in.

The sub-circuits 5A, 5B, 5C are equal to each other, therefore FIG. 1 shows the electrical equivalent of only sub-circuit 5A (first sub-circuit 5A).

Subsequently, the sub-circuits 5A, 5B, 5C, as well as their constituent parts, are indicated by the number only, when not necessary for the identification of the specific sub-circuit, or by the letter (A, B, C) where useful for understanding.

The sub-circuits 5A, 5B, 5C are each formed by a respective vertical branch 7 and a respective horizontal branch 8, mutually coupled at a central node (hereinafter generically indicated by 20), of which FIG. 1 shows only central node 20A of the horizontal branch, indicated by 8A, of the first sub-circuit 5A. Similar vertical branches (not numbered) and horizontal branches 8B, 8C (represented only schematically) are comprised in the sub-circuits 5B, 5C.

In detail, in each sub-circuit 5A, 5B, 5C, an inductive element 21 is coupled between the respective first connection node 2A, 2B, 2C and the respective central node 20.

The vertical branch 7 of each of the sub-circuits 5A, 5B, 5C comprises two power components 18, 19, series-connected between the respective fourth connection node 10A, 10B, 10C and the respective fifth connection node 11A-11C.

The power components 18, 19 of the vertical branches 7 of the sub-circuits 5A, 5B, 5C may be formed by silicon or silicon carbide MOSFET transistors, by IGBTs or by MOSFET transistors made by using gallium-nitride-based technology, as described in detail in aforementioned Italian patent 102022000006563.

Furthermore, the power components 18, 19 of the vertical branches 7 of the sub-circuits 5A, 5B, 5C may be formed by diodes or have gate terminals coupled with the outside, for example to an associated control circuit (not shown), in a per se known manner.

In practice, the vertical branches 7 of the sub-circuits 5A, 5B, 5C overall form a three-phase inverter which may be implemented as described in already mentioned Italian patent 102022000006563. The vertical branches 7 of the sub-circuits 5A, 5B, 5C may be packaged in a single case, as described in Italian patent 102022000006563, to form a single packaged inverter device.

The horizontal branch 8A, 8B, 8C of each of the sub-circuits 5A, 5B, 5C comprises a first and a second power device 23, 24, coupled between the central node 20 of the respective sub-circuit 5A, 5B, 5C and the respective third connection node 9A, 9B, 9C.

The power devices 23, 24 of the horizontal branch 8 are coupled in a back-to-back configuration, in a source-to-source configuration (i.e., with coupled source regions) or in a drain-to-drain configuration (i.e., with coupled drain regions), as discussed in detail below.

FIG. 1 shows the coupling node 6A between the first power device 23 and the second power device 24 of the horizontal branch 8A of the first sub-circuit 5A. The second and the third sub-circuits 5B, 5C have respective coupling nodes 6B, 6C (indicated in the subsequent Figures) similarly arranged.

The power devices 23, 24 may be MOSFET transistors in silicon or silicon carbide (SiC) based technology or be IGBTs, characterized by a wide source metallization (forming a source pad, or terminal) on one side of the die having the power devices 23, 24 integrated therein, a gate pad (or terminal) on the same side of the source pad, and a wide drain metallization (forming a drain pad, or terminal) on a side opposite to the source pad.

For example, FIG. 2 shows a possible implementation of the power devices 23, 24 as charge-balanced transistors (also referred to as “superjunction” transistors), integrated into a silicon die.

In detail, the power device 23, 24 shown in FIG. 2 comprises a substrate 25 having an upper surface 25A and a lower surface 25B.

The substrate 25 forms a drain region 26 and is electrically contacted through a drain metal layer 27, forming the drain pad and extending on the lower surface 25B of the substrate 25.

Source regions 28 face the upper surface 25B and are contacted by a source metal layer 29 forming the source pad and extending on the upper surface 25A of the substrate 25.

Insulated gate regions 30 extend above the upper surface 25A of the substrate 25 and have respective gate conductive portions 31 coupled to a gate pad, not visible.

The power device 23, 24 shown in FIG. 2 is integrated in a die indicated below by 51 having a first and a second main surface 51A, 51B.

Alternatively, the power devices 23, 24 may be MOSFET transistors in the GaN technology, characterized by source, drain and gate pads on a same side of the die.

For example, FIG. 3 shows a possible implementation of the power devices 23, 24 as planar power MOSFET transistors in the gallium nitride (GaN) technology.

In detail, the power device 23, 24 shown in FIG. 3 comprises a semiconductor body 35, having an upper surface 35A and a lower surface 35B.

The semiconductor body 35 here comprises a substrate 36, for example of silicon, defining the lower surface 35B; a buffer layer 37, of gallium nitride (GaN), on the substrate 35; a channel layer 38, for example of gallium nitride (GaN), on the buffer layer 37; and a barrier layer 39, for example of aluminum gallium nitride (AlGaN), on the channel layer 38 and defining the upper surface 35A of the semiconductor body 35.

A gate region 41, of conductive material, for example of gallium nitride, with P-type conductivity (pGaN) extends above the barrier layer 39; a gate contact region 42, of metal, for example TiN/AlCu/TiN, extends above and is in direct electrical contact with the gate region 41, forming a gate pad (or terminal); a source contact region 43, of metal, for example Ti/AlCu/TiN, extends above and is in direct electrical contact with the barrier layer 39, on a first side of the gate region 41, forming a source pad (or terminal); a drain contact region 44, of metal, for example of Ti/AlCu/TiN, extends above and is in direct electrical contact with the barrier layer 39, on a second side, opposite to the first side, of the gate region 41, forming a drain pad (or terminal); and an insulating layer 45, for example of silicon oxide, extends above the upper surface 35A of the semiconductor body 35, between the gate region 41, the gate contact region 42, the source contact region 43 and the drain contact region 44.

The power device 23, 24 shown in FIG. 3 is integrated in a die indicated below by 251 and having a main surface 251A with all the contact regions 42-44 facing thereon.

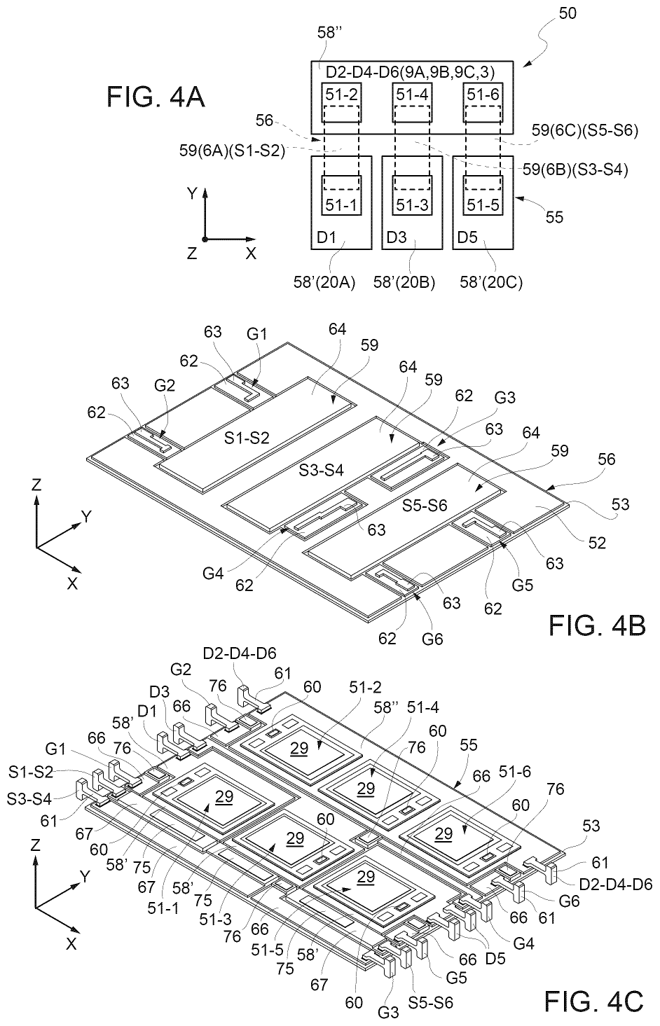

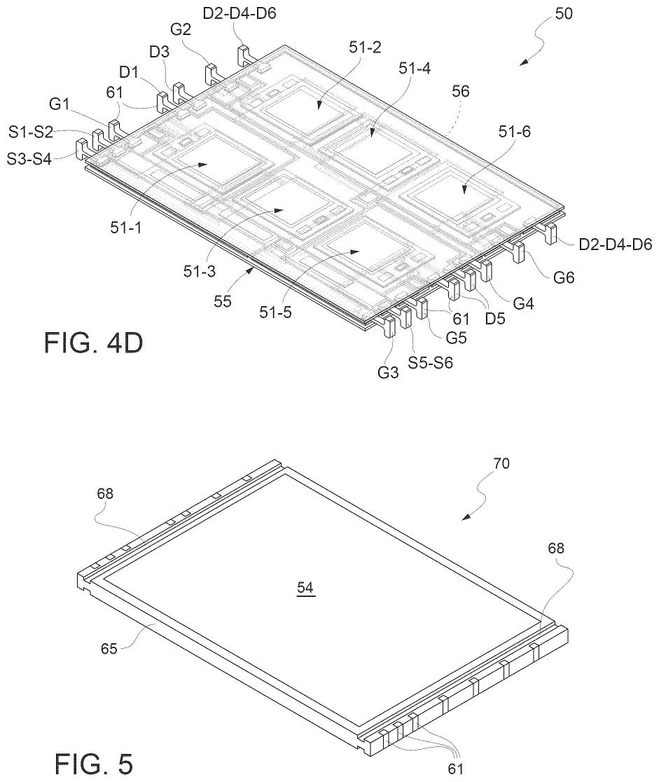

Returning to FIG. 1, the horizontal branches 8A, 8B, 8C of the sub-circuits 5A, 5B, 5C may be packaged in a single housing, to form a single device including all the power devices 23, 24, as discussed hereinbelow with reference to FIGS. 4A-9D.

In detail, FIGS. 4A-4D show an electronic device 50 comprising, in a single packaged structure, the three horizontal branches 8A, 8B, 8C of the sub-circuits 5A, 5B, 5C in case the power devices 23, 24 are of the type shown in FIG. 2 or have a similar configuration of the external pads, i.e., a drain pad arranged on a main surface of the source and gate pads arranged on the opposite main surface.

Furthermore, FIGS. 4A-4D refer to an electronic device 50 wherein the power devices 23, 24 are coupled in a source-to-source configuration.

The electronic device 50 comprises six dice, indicated by the sole number 51 where not necessary to distinguish them and indicated as first die 51-1, second die 51-2, third die 51-3, fourth die 51-4, fifth die 51-5 and sixth die 51-6, where useful.

The dice 51 are typically all the same, and each implement a respective power device 23, 24 of the sub-circuits 5A, 5B, 5C of FIG. 1.

In particular, with the arrangement shown in FIGS. 4A-4D, the first, the third and the fifth dice 51-1, 51-3, 51-5 implement the first power device 23 of the sub-circuits 5A, 5B, 5C of FIG. 1; the second, the fourth and the sixth dice 51-2, 51-4 and 51-6 implement the second power device 24 of the sub-circuits 5A, 5B, 5C of FIG. 1.

The dice 51 are here arranged side by side and sandwiched between a first and a second substrate element, hereinafter referred to as lower substrate element 55 and upper substrate element 56.

The substrate elements 55, 56 form connection structures between the first power devices 23 and the second power devices 24 of the sub-circuits 5A, 5B, 5C of FIG. 1, only some whereof (relating to the drain and source connections) are shown in FIG. 4A.

In particular, in FIG. 4A, the areas of the lower substrate element 55 are indicated by solid lines; the areas of the upper substrate element 56 are indicated in ghost. Conversely, the substrate elements 55, 56 are shown in detail in FIGS. 4B-4D.

The substrate elements 55, 56, also forming thermal dispersion structures, are multilayer structures and may be formed by DBC (Direct Bonded Copper), having a first conductive layer, typically a metal layer; a second conductive layer, also typically a metal layer; and an insulating layer, typically a ceramic layer, arranged between the first and the second conductive layers, as described in detail in aforementioned Italian patent 102022000006563.

In particular, one of the conductive layers of each of the substrate elements 55, 56 faces the dice 51 and is patterned to form “islands” and other electrical connection regions, as described in detail below, while the other conductive layer is arranged towards the outside of the electronic device 50 and is typically planar or of any shape suitable for dissipation.

In FIGS. 4B-4D, the patterned conductive layer, facing the dice 51, of the substrate elements 55, 56 is indicated by 52 and the insulating layer is indicated by 53. The conductive layer facing the outside of only the upper substrate element 56 is visible in FIG. 5, and indicated by 54.

In detail, in FIG. 4A, the dice 51 implementing the first power device 23 of the sub-circuits 5A, 5B, 5C of FIG. 1 (first, third and fifth dice 51-1, 51-3 and 51-5) are aligned with each other, for example parallel to a first axis X of a Cartesian reference system XYZ. Similarly, the dice 51 implementing the second power device 24 (second, fourth and sixth dice 51-2, 51-4 and 51-6) are aligned with each other, in the example, parallel to the first axis X.

Furthermore, the two dice 51 implementing each horizontal branch 8 of the sub-circuits 5A, 5B, 5C of FIG. 1 (pair formed by the first and the second dice 51-1, 51-2, pair formed by the third and the fourth dice 51-3, 51-4 and pair formed by the fifth and the sixth dice 51-5, 51-6) are aligned with each other, in the example, parallel to a second axis Y of the Cartesian reference system XYZ.

It should be noted that the arrangement of the dice 51 and the connections thereof shown in FIG. 4A represents an idealization, and the exact alignment of the dice 51 is not essential.

In FIG. 4A (as in FIGS. 4B and 4C), for a better understanding of the topology, the drain connection paths associated with the drain terminals of the dice 52 are identified by D1, D2, D3, D4, D5, D6; the gate connection paths associated with the gate terminals of the dice 52 are identified by G1, G2, G3, G4, G5, G6, and the source connection paths associated with the source terminals of the dice 52 are identified by S1, S2, S3, S4, S5, S6, wherein the number 1-6 refers to the specific considered die 51.

By virtue of the type of the electronic device 50, the drain paths D2, D4 and D6 are coupled and form a common drain path indicated below and in the figures by D2-D4-D6; furthermore, the source paths are coupled two by two and form three paired-source paths indicated below and in the figures by S1-S2, S3-S4 and S5-S6.

In FIG. 4A, the dice 51 are arranged to have the second main surface 51B of FIG. 2 (having the drain metallization 27 thereon) facing (i.e., looking toward) one of the substrate elements, here the lower substrate element 55. Furthermore, the dice 51 are arranged to have the first main surface 51A of FIG. 2 (having the source metallization 29 and the gate metallization thereon, not visible in FIG. 2 and indicated by 60 in FIG. 4B) facing (i.e., looking toward) the other of the substrate elements, here, the upper substrate element 56.

In this embodiment, therefore, the lower substrate element 55 forms separate drain connections (D1, D3, D5) for the first power devices 23 of the sub-circuits 5A, 5B, 5C of FIG. 1 and a common drain connection (D2-D4-D6) for the second power devices 24 of the sub-circuits 5A, 5B, 5C of FIG. 1.

Furthermore, the upper substrate element 56 forms source connections between each first power device 23 and the respective second power device 24 of each sub-circuit 5A, 5B, 5C of FIG. 1 (paired-source islands 59).

In detail, in FIG. 4A, the lower substrate element 55 forms:
three separate drain islands 58′ for coupling the drain metallizations 27 of FIG. 2 respectively to the first, the third and the fifth dice 51-1, 51-3 and 51-5 (i.e., to the dice 51 implementing the first power device 23 of the sub-circuits 5A, 5B, 5C of FIG. 1);
a common drain island 58″ for coupling the drain metallizations 27 of FIG. 2 to the second, the fourth and the sixth dice 51-2, 51-4 and 51-6 (i.e., to the dice 51 implementing the second power device 24 of the sub-circuits 5A, 5B, 5C of FIG. 1); and
three paired-source islands 59, respectively to electrically connect to each other the source metallizations 29 of the first and the second dice 51-1, 51-2 (source connection paths S1 and S2), the source metallizations 29 of the third and the fourth dice 51-3, 51-4 (source connection paths S3 and S4), and the source metallizations 29 of the fifth and the sixth dice 51-5, 51-6 (source connection paths S5 and S6).

In this manner, each separate drain island 58′ (on the respective drain connection path D1, D2, D3, FIG. 4A) may be coupled to the respective central node, indicated here by 20A, 20B, 20C of the sub-circuits 5A, 5B, 5C of FIG. 1; the common drain island 58″ (on the drain connection path D2-D4-D6 and forming the third connection nodes 9A, 9B, 9C, FIG. 4A) may be coupled to the second connection node 3 of the energy conversion unit 1 of FIG. 1; and each paired-source island 59 (on the respective paired-source connection path S1-S2, S3-S4 and S5-S6, FIG. 4A) allows the connection of the respective first power device 23 to the corresponding second power device 24 of the sub-circuits 5A, 5B, 5C of FIG. 1 (at respective intermediate nodes 6A, 6B, 6C).

FIG. 4A does not show, as indicated above, the gate connections of the dice 51 with the outside, formed through connection regions formed here in both substrate elements 55, 56 and shown in detail in FIGS. 4B-4D.

A possible implementation of the shape and arrangement of the drain 58′, 58″ and source 59 islands of FIG. 4A, of their external connection, as well as of the shape and connections of the gate metallizations for forming the connections of the power devices 23, 24 of FIG. 1 is visible in detail in FIGS. 4B-4D.

FIGS. 4B-4D also show leads 61 that allow the external connection of the electronic device 50.

In particular, as specifically shown in FIG. 4C, in the embodiment shown, the electronic device 50 is connected to the outside through surface mounting leads 61 that are coupled, typically soldered, to drain, source and gate connection regions here formed by the patterned conductive layer 52 of the lower substrate member 55, as described in detail below.

The leads 61 are connected to the respective drain and source islands 58′, 58″, 59 as well as to the gate paths in the manner described below through connection regions described below with reference to FIG. 4C.

FIG. 4C shows the dice 51 coupled, in particular soldered, to the patterned conductive layer 52 of the lower substrate element 55. In FIG. 4C the source metallizations 29 and the gate metallizations 60 of the dice 51 are also visible.

With particular reference to FIG. 4B, the patterned conductive layer 52 of the upper substrate element 56 forms, in addition to the three paired-source islands 59, six gate islands 62 each intended to couple to a respective gate metallization 60 of the dice 51.

In particular, in the embodiment shown, the contact between the gate islands 62 and the gate metallizations 60 occurs through gate protrusions 63 protruding from the same gate islands 62.

Furthermore, the contact between the paired-source islands 59 and the source metallizations 29 occurs through source protrusions 64 protruding from the same paired-source islands 59.

In a per se known manner, the source and gate islands 59, 62 and the protrusions 63, 64 in the patterned conductive layer 52 of the upper substrate element 56 may be obtained by selectively etching, with differential depth, the same patterned conductive layer 52.

With particular reference to FIG. 4C, the patterned conductive layer 52 of the lower substrate element 55 forms, in addition to the three separate drain islands 58′ and the common drain island 58″, gate connection regions 66 and source connection regions 67.

In detail, the patterned conductive layer 52 of the lower substrate element 55 forms six gate connection regions 66, each intended to couple to a respective gate island 62 in the upper substrate clement 56 (FIG. 4B), and three source connection regions 67, each intended to couple to a respective paired-source island 59 in the upper substrate element 56 (FIG. 4B).

The patterned conductive layer 52 of the lower substrate element 55 also forms, in the embodiment shown in FIG. 4C, protrusions 75 of the source connection regions 67 and protrusions 76 of the gate connection regions 66, for connecting the same gate connection regions 66 and source connection regions 67 to the gate 62 and paired-source 59 islands of FIG. 4A through the corresponding source protrusions 63 and 64.

The protrusions in the patterned conductive layer 52 of the lower substrate element 55 may also be obtained by selectively etching, with differential depth, the same patterned conductive layer 52.

The source protrusions 64 in the upper substrate element 56 and the source protrusions 75 in the lower substrate clement 55 allow the paired-source islands 59, in addition to compensating the thickness of the dice 51, to also extend above the gate connection regions 66 and the drain islands 58′, 58″, without risks of electrical contact, as is also noted in FIG. 4D.

It should be noted that the shown shape of the different islands 59, 62 and the connection regions 58′, 58″, 66, 67 may vary from what has been illustrated. Obviously, to allow electrical coupling they need to be configured and arranged so that, after superimposing and coupling the first and the second substrate elements 55, 56, the islands and the respective connection regions are superimposed.

In particular, the paired-source islands 59 are configured and arranged to have portions that are vertically (in the direction of the vertical axis Z of the Cartesian reference system XYZ) overlying the source metallizations 29 of the respective dice pairs 51-1/51-2, 51-3/51-4, 51-5/51-6, and portions overlying the source connection regions 67.

More in particular, the source protrusions 64 in the patterned conductive layer 52 of the upper substrate element 56 are vertically overlying the source metallizations 29 of the respective dice pairs 51-1/51-2, 51-3/51-4, 51-5/51-6 and the protrusions 75 of the source connection regions 67.

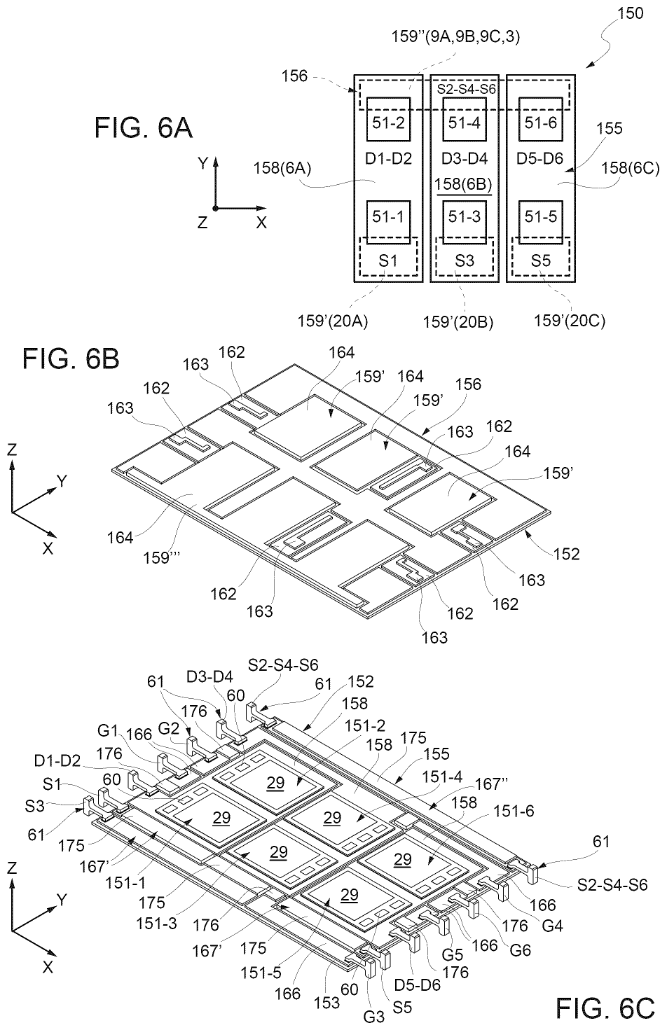

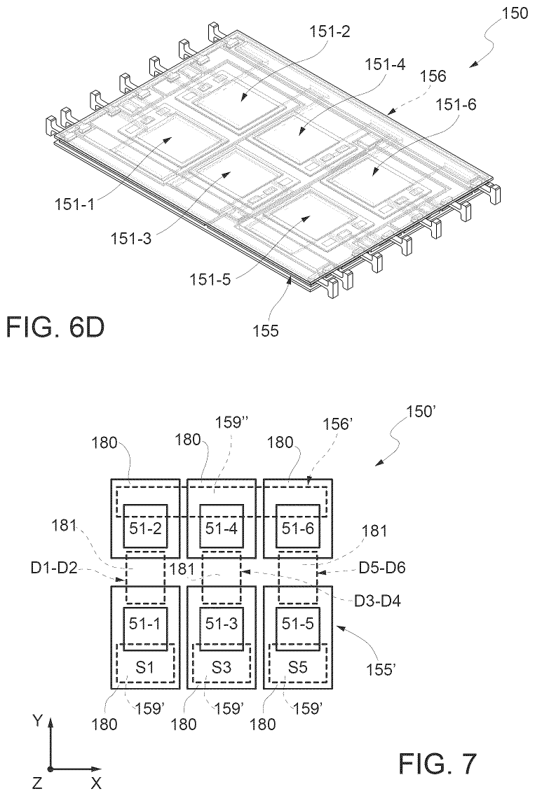

For example, in FIG. 6B, the paired-source islands 59 and the source protrusions 64 are generally rectangular, and the area of the paired-source islands 59 is greater than that of the source protrusions 64.

Furthermore, each gate island 62 (and in particular, in the embodiment shown, each gate protrusion 63) is configured and arranged to vertically overly the gate metallization 60 of a respective die 51 and the protrusion 76 of a respective gate connection region 66.

For example, in FIG. 6B, the gate islands 62 have a generally rectangular shape and the gate protrusions 63 have an elongated shape.

Respective leads 61 are soldered to the gate connection regions 66, to the source connection regions 67 and to the drain islands 58′, 58″.

In FIG. 4C, for ease of understanding of the connections, the connection paths formed by the connections of FIG. 4A, and therefore the drain connection paths D1, D3, D5, D2-D4-D6, the gate connection paths G1, G2, G3, G4, G5, G6, and the paired-source connection paths S1-S2, S3-S4, S5-S6, are indicated on the leads 61.

FIG. 4D shows the electronic device 50 after superimposing and coupling the upper substrate element 56 on/to the lower substrate element 55, after turning the upper substrate element 56 around the first axis X of the Cartesian reference system XYZ. In FIG. 4D, the upper substrate element 56 is shown in ghost, to highlight the connections between the source and gate islands 59, 62 and the respective source and gate connection regions 67, 66 of the lower substrate element 55.

FIG. 5 shows the electronic device 50 after packaging, for example by molding a package 65 of insulating material, for example of resin. The packaged electronic device thus obtained is indicated by 70.

Here, the leads 61 have a same height as the package 65, to allow stacking of the electronic device 50 with other equal electronic devices 50, if desired.

The electronic device 50 of FIG. 5 has grooves 68 in the package 65, useful in case the electronic device 50 operates at very high voltages/powers (for example, in case of operativeness up to 1200-2000 V) and advanced insulation conditions (high creepage distances) are required, as discussed in aforementioned Italian patent 102022000006563.

FIGS. 6A-6D refer to an electronic device 150 comprising, in a single packaged structure, the three horizontal branches 8A, 8B, 8C of the sub-circuits 5A, 5B, 5C in case the power devices 23, 24 are of the type shown in FIG. 2 or have a similar configuration of the external pads, i.e., drain pad arranged on a main surface of the die and source and gate pads arranged on the opposite main surface.

The dice are therefore the same as the electronic device 50 of FIGS. 4A-4D and are therefore indicated by the same reference numbers (51, and, where useful to distinguish them, 51-1, 51-2, 51-3, 51-4, 51-5 and 51-6).

Furthermore, FIGS. 6A-6D refer to an electronic device 150 wherein the power devices 23, 24 are coupled in a drain-to-drain configuration.

In practice, the electronic device 150 of FIGS. 6A-6D has a general structure similar to the electronic device 50 of FIGS. 4A-4D. Therefore, components similar to those of FIGS. 4A-4D have been indicated by reference numbers increased by 100.

In particular, in FIGS. 6A-6D, the source and drain connection paths are different and coupled differently with respect to FIGS. 4A-4D.

In detail, in FIGS. 6A-6D, the source paths S1, S3 and S5 of the first, third and fifth dice 61-1, 61-3 and 61-5 are separated; the source paths S2, S4 and S6 of the second, fourth and sixth dice 61-2, 61-4 and 61-6 are coupled and form a common source path indicated below and in the Figures by S2-S4-S6; furthermore the drain paths of the dice 51 are coupled two by two and form three paired-drain paths indicated below and in the Figures by D1-D2, D3-D4 and D5-D6.

For the rest, in FIGS. 6A-6D, the dice 51 are arranged in a similar manner to what has previously been described for the lower substrate element and the upper substrate element (now indicated by 155, 156), with the drain metallizations arranged facing the lower substrate element 155 and the gate and source metallizations facing the upper substrate element 156.

Here, as shown in the schematic representation of FIG. 6A, the lower substrate element 155 forms three paired-drain islands 158 to electrically connect to each other the drain metallizations of the first and the second dice 51-1, 51-2 (paired-drain connection path D1-D2); the drain metallizations of the third and the fourth dice 51-3, 51-4 (paired-drain connection path D3-D4); and the drain metallizations of the fifth and the sixth dice 51-3, 51-4 (paired-drain connection path D5-D6).

Furthermore, the upper substrate element 156 forms three separate source islands 159′ for coupling the source metallizations 29 of FIG. 2, respectively to the first, the third and the fifth dice 51-1, 51-3 and 51-5, and a common source island 159″ for coupling the source metallizations 29 of FIG. 2 to the second, the fourth and the sixth dice 51-2, 51-4 and 51-6.

In this manner, each separate source island 159′ (on the respective source connection path S1, S3, S5, FIG. 6A) may be coupled to the respective central node 20 of the sub-circuits 5A, 5B, 5C of FIG. 1; the common source island 159″ (on the source connection path S2-S4-S6, FIG. 6A) may be coupled to the second connection node 3 of the energy conversion unit 1 of FIG. 1; and each paired-drain island 158 (on the respective paired-drain connection path D1-D2, D3-D4 and D5-D6, FIG. 6A) allows the connection of the respective first power device 23 to the corresponding second power device 24 of the sub-circuits 5A, 5B, 5C of FIG. 1.

A possible implementation of the shape and arrangement of the drain and source islands 158, 159′, 159″ of FIG. 6A, of their external connection, as well as of the shape and the connections of the gate metallizations to form the power devices 23, 24 of FIG. 1 in drain-to-drain configuration is visible in detail in FIGS. 6B-6D.

Also in the electronic device 150 of FIGS. 6B-6D, the drain and source islands 158, 159′, 159″, their connection regions as well as the gate islands and their connection regions are formed in the patterned conductive layers (here indicated by 152) of the substrate elements 155, 156 and the connections towards the outside are provided through leads, again indicated by 61 and attached, in particular soldered, on the regions and islands formed on the lower substrate element 155, having the dice 51 also bonded thereto.

With particular reference to FIG. 6B, the patterned conductive layer 152 of the upper substrate element 156 forms, in addition to the three separate source islands 159′ and the common source island 159″, six gate islands 162, similar to the gate islands 62 of FIG. 4B, although of a different shape.

Also here, gate protrusions 163 and source protrusions 164 ensure contact between the islands 162, 159′, 159″ and the gate 60 and source 29 metallizations thereof on the dice 51.

With particular reference to FIG. 6C, the patterned conductive layer 152 of the lower substrate element 155 forms, in addition to the three paired-drain islands 158, gate connection regions 166, three separate source connection regions 167′ and a common source connection region 167″.

In detail, the patterned conductive layer 152 of the lower substrate element 155 forms six gate connection regions 166, each intended to couple to a respective gate island 162 in the upper substrate element 156 (FIG. 6B); three separate source connection regions 167′, each intended to couple to a respective separate source island 159′; and a common source connection region 167″, intended to couple to the common source island 159″ in the upper substrate element 156 (FIG. 6B).

The patterned conductive layer 152 of the lower substrate element 155 of FIG. 6C also forms source protrusions 175 and gate protrusions 176.

Also here, the source islands 159′, 159″ in the upper substrate element 156 are configured and arranged to have portions vertically overlying the source metallizations 29 of the respective dice 51 and portions overlying the source connection regions 167 in the lower substrate clement 155.

More in particular, the source protrusions 164 vertically overly the source metallizations 29 of the dice 51 and the protrusions 175 of the source connection regions 167′, 167″.

Furthermore, each gate island 162 (and in particular, in the embodiment shown, each gate protrusion 163) is configured and arranged to have a portion vertically overlying the gate metallization 60 of a respective die 51 and a portion vertically overlying the protrusion 176 of a respective gate connection region 166.

Respective leads 61 are bonded to the gate connection regions 166, to the source connection regions 167′ and 167″ and to the drain islands 158.

In FIG. 6C, for case of understanding of the connections, the connection paths formed by the connections of FIG. 6A, and therefore the drain connection paths D1-D2, D3-D4, D5-D6, the gate connection paths G1, G2, G3, G4, G5, G6, and the source connection paths S1, S3, S5, S2-S4-S6, are indicated on the leads 61.

FIG. 6D shows the electronic device 150 after superimposing and coupling the upper substrate element 156 on/to the lower substrate element 155. In FIG. 6D, the upper substrate element 156 is shown in ghost, to highlight the connections between the source and gate islands 159′, 159″, 162 and the respective source and gate connection regions 167, 166.

The electronic device 150 of FIG. 6D, after packaging, for example by molding a package of insulating material, has an external shape similar to that of the packaged electronic device 70 of FIG. 5, except for the position of the leads 61.

FIG. 7 shows a variant of the mutual arrangement of the drain connection regions, in case of power devices 23, 24 of the type shown in FIG. 2 (or with a similar arrangement of the external pads) formed and coupled in a drain-to-drain configuration.

In the arrangement of FIG. 7, instead of having three paired-drain islands 158 formed in the patterned conductive layer 152 of the lower substrate element 155 and connecting, two by two, the drain metallizations 27 of the dice 51, the lower substrate element (here indicated by 155′) forms six separate drain islands 180 and the two separate drain islands 180 on each paired-drain connection path D1-D2, D3-D4 and D5-D6 (relating to the sub-circuits 5A, 5B and 5C of FIG. 1) are coupled through a respective bridge element 181 formed in the patterned conductive layer 152 of the upper substrate element 156′.

These couplings between the separate drain islands 180 and the three bridge elements 181 also occur through protrusions similar to the protrusions 163, 164, 175, 176 of FIGS. 6B, 6C.

The separate drain islands 180 are coupled to respective leads 61, in a similar manner to what shown in FIG. 6C.

The source connections (the separate source islands 159′, the common source island 159″ in the upper substrate element 156′, the separate source connection regions 167′, and the common source connection regions 167″ in the lower substrate element 155) may be formed substantially as shown in FIGS. 6B and 6C.

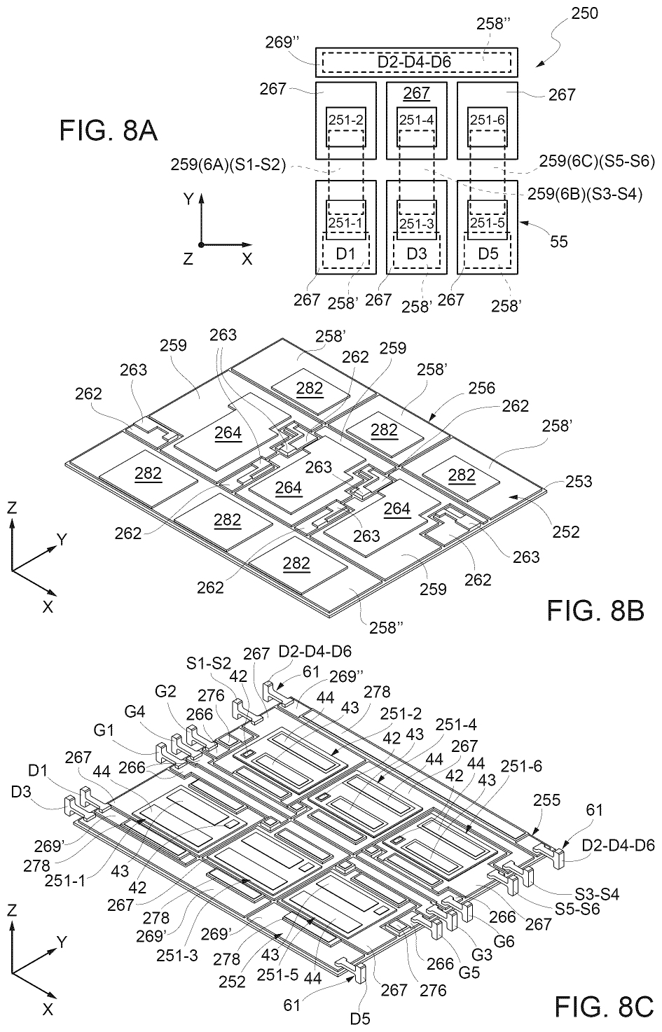

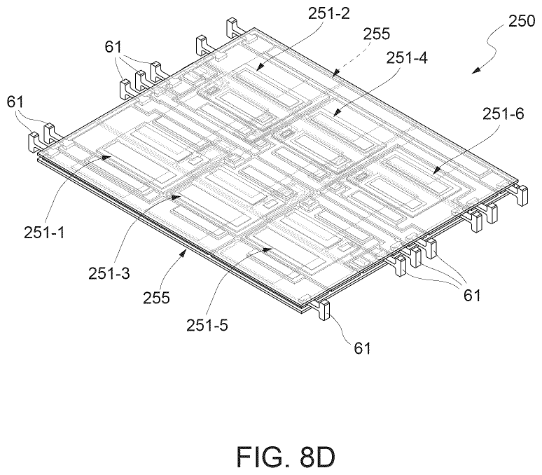

FIGS. 8A-8D refer to an electronic device 250 comprising, in a single packaged structure, the three horizontal branches 8A, 8B, 8C of the sub-circuits 5A, 5B, 5C when the power devices 23, 24 are of the type shown in FIG. 3 or have a similar configuration of the external pads, i.e., all the external pads arranged on the same main surface of the die (gate metallizations 42, source metallizations 43 and drain metallizations 44 of FIG. 3).

Furthermore, FIGS. 8A-8D refer to an electronic device 250 wherein the power devices 23, 24 are coupled in a source-to-source configuration.

The electronic device 250 comprises six dice, indicated by only number 251 where not necessary to distinguish them and indicated as first die 251-1, second die 251-2, third die 251-3, fourth die 251-4, fifth die 251-5 and sixth die 251-6, where useful.

Typically, the dice 251 are the same, and implement the power devices 23, 24 of the sub-circuits 5A, 5B, 5C of FIG. 1, similarly to what described for the dice 51 of FIG. 4A.

Furthermore, they are arranged side by side with each other and sandwiched between the substrate elements, indicated here by 255, 256. Also here, FIG. 8A schematically shows only some connection parts between the first power devices 23 and the second power devices 24 of the sub-circuits 5A, 5B, 5C of FIG. 1, while FIGS. 8B-8D show in detail the shape and arrangement of the conductive connection structures.

In the electronic device 250, by virtue of the arrangement of the gate metallizations 42, source metallizations 43 and drain metallizations 44 (FIGS. 3 and 8C) on the same main surface 251A of the dice 251, the connection islands in direct contact therewith (hereinafter referred to as “islands”) are formed in a same conductive layer 252.

In detail, the dice 251 are mounted with the lower surface 35B of FIG. 3 facing the lower substrate element 255 and the gate metallizations 42, source metallizations 43 and drain metallizations 44 of FIG. 3 facing the upper substrate element 256.

Also here, the leads 61 are attached to the lower substrate element 255, as shown in detail in FIG. 8C.

The electronic device 250 therefore has a connection configuration conceptually similar to the electronic device 50 of FIGS. 4A-4B, except for the drain connection regions (in contact with the drain metallizations 44 of FIG. 3) here, as mentioned, formed in the patterned conductive layer 252 of the upper substrate element 256, as described in detail below.

Consequently, components of the electronic device 250 similar to the electronic device 50 of FIGS. 4A-4D are indicated with reference numbers increased by 200 with respect to FIGS. 4A-4D.

In particular, the drain and source connection paths of the electronic device 250 are the same as in the electronic device 50 of FIGS. 4A-4D and comprise coupled drain paths D2, D4 and D6 forming a common drain path D2-D4-D6; the source paths coupled two by two and forming three paired-source paths S1-S2, S3-S4 and S5-S6. The drain paths D1, D3 and D5 of the first, third and fifth dice 61-1, 61-3 and 61-5 are separated.

In this embodiment, therefore, FIG. 8A, the upper substrate element 256 forms separate drain islands 258′ for the first power devices 23 of the sub-circuits 5A, 5B, 5C of FIG. 1 and a common drain island 258″ for the second power devices 24 of the sub-circuits 5A, 5B, 5C of FIG. 1.

Furthermore, the upper substrate element 256 forms three paired-source islands 259 between each first power device 23 and the respective second power device 24 of the sub-circuits 5A, 5B, 5C of FIG. 1.

FIG. 8A shows a common drain connection region 269″ (coupled to the common drain island 258″), formed in the lower substrate element 255. FIG. 8A does not show separate drain connection regions formed in the lower substrate element 255 and coupled to the separate drain islands 258′.

Conversely, FIG. 8A shows six source connection regions 267, having the dice 251 bonded, for example soldered, thereto as better shown in FIG. 8C.

It should be noted that the source connection regions 267 aligned along the second axis Y of the Cartesian reference system XYZ in FIG. 8A, although separated to allow gate connections (as visible in FIG. 8C), are actually electrically coupled.

A possible implementation of the shape and arrangement of the drain and source islands 258′, 258″ and 259 of FIG. 8A, of their external connection, as well as of the shape and connections of the gate metallizations to form the power devices 23, 24 of FIG. 1 is visible in detail in FIGS. 8B-8D.

With particular reference to FIG. 8B, the patterned conductive layer 252 of the upper substrate element 256 forms, in addition to the three paired-source islands 259, the separate drain islands 258′ and the common drain island 258″, six gate islands 262 intended to couple with the gate metallizations 42 (FIG. 8C) of the dice 251.

Furthermore, in the embodiment shown in FIG. 8B, the contact between the gate islands 262 and the respective gate metallizations 42 (FIG. 8C) occurs through gate protrusions 263 protruding from the same gate islands 62.

Similarly, the contact between the paired-source islands 259 and the respective source metallizations 43 (FIG. 8C) occurs through source protrusions 264 protruding from the same paired-source islands 59.

Furthermore, here, the contact between the separate drain islands 258′ and the respective drain metallizations 44 (FIG. 8C, for the first power devices 23 of the sub-circuits 5A, 5B, 5C of FIG. 1), as well as the contact between the common drain island 258″ and the drain metallizations 44 (FIG. 8C, for the second power devices 24 of the sub-circuits 5A, 5B, 5C of FIG. 1) occurs through drain protrusions 282 protruding from the same drain islands 258′, 258″.

With particular reference to FIG. 8C, the patterned conductive layer 252 of the lower substrate element 255 forms, in addition to the common drain connection region 269″ (intended to couple to the common drain island 258″, FIG. 8B) and to the source connection regions 267:
three separate drain connection regions 269′, each intended to couple to a respective separate drain island 258′ of FIG. 8B; and
six gate connection regions 266, each intended to couple to a respective gate island 262 in the upper substrate element 256 of FIG. 8B.

The patterned conductive layer 252 of the lower substrate element 255 forms, in the embodiment shown in FIG. 8C, source protrusions 275, gate protrusions 276 and drain protrusions 278 for coupling to corresponding source protrusions 264, gate protrusions 263 and drain protrusions 282 of FIG. 8B.

Here, the source islands 259 are configured and arranged to have portions vertically (in the direction of the vertical axis Z of the Cartesian reference system XYZ) overlying the source metallizations 43 of the respective dice pairs 251-1/251-2, 251-3/251-4, 251-5/251-6, and portions overlying the source connection regions 267.

More in particular, the source protrusions 264 are vertically overlying the source metallizations 43 of the dice 251 and the protrusions 275 of the source connection regions 267.

Furthermore, each gate island 262 (and in particular, in the embodiment shown, each gate protrusion 263) is configured and arranged to have portions vertically overlying the gate metallization 42 of a respective die 251 and the protrusion 276 of a respective gate connection region 266.

Here, each drain island 258′, 258″ (and in particular, in the embodiment shown, each drain protrusion 263) is configured and arranged to vertically overly the drain metallization 44 of a respective die 251 and the protrusion 278 of a respective drain connection region 269′, 269″.

The source protrusions 264 in the upper substrate element 256 and the source protrusions 275 in the lower substrate element 255 here allow the paired-source islands 259 to also extend above the gate connection regions 266 without risk of electrical contact, as visible also in FIG. 8D.

The respective leads 61 are bonded to the gate connection regions 266, to the source connection regions 267 and to the drain islands 269′, 269″.

In FIG. 8C, for case of understanding of the connections, the connection paths formed by the connections of FIG. 8A, and therefore the drain connection paths D1, D3, D5, D2-D4-D6, the gate connection paths G1, G2, G3, G4, G5, G6, and the paired-source connection paths S1-S2, S3-S4, S5-S6, are indicated on the leads 61.

FIG. 8D shows the electronic device 250 after superimposing and coupling the upper substrate element 256 on/to the lower substrate element 256. In FIG. 8D, the upper substrate element 256 is shown in ghost, to highlight the connections between the common drain connection region 269″ and the common drain island 258″; between the separate drain connection regions 269′ and the respective separate drain islands 258′; between the source connection regions 267 and the respective paired-source islands 259; and between the gate connection regions 266 and the respective gate islands 262.

The electronic device 250, after packaging, for example by molding a package of insulating material, has an external shape similar to that of the packaged electronic device 70 of FIG. 5, except for the position of the leads 61.

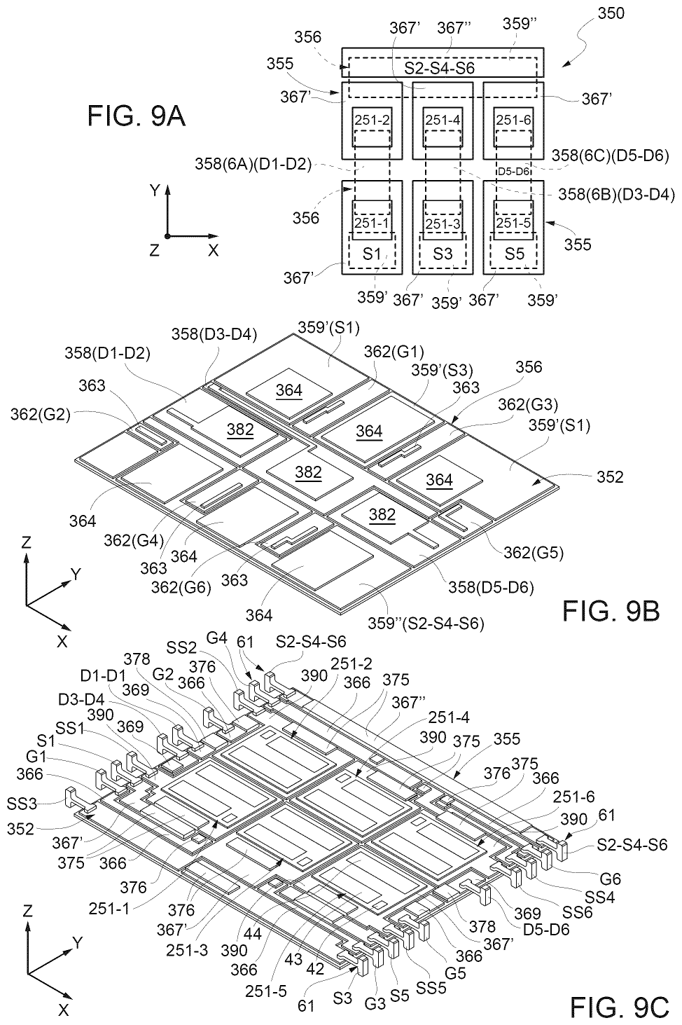

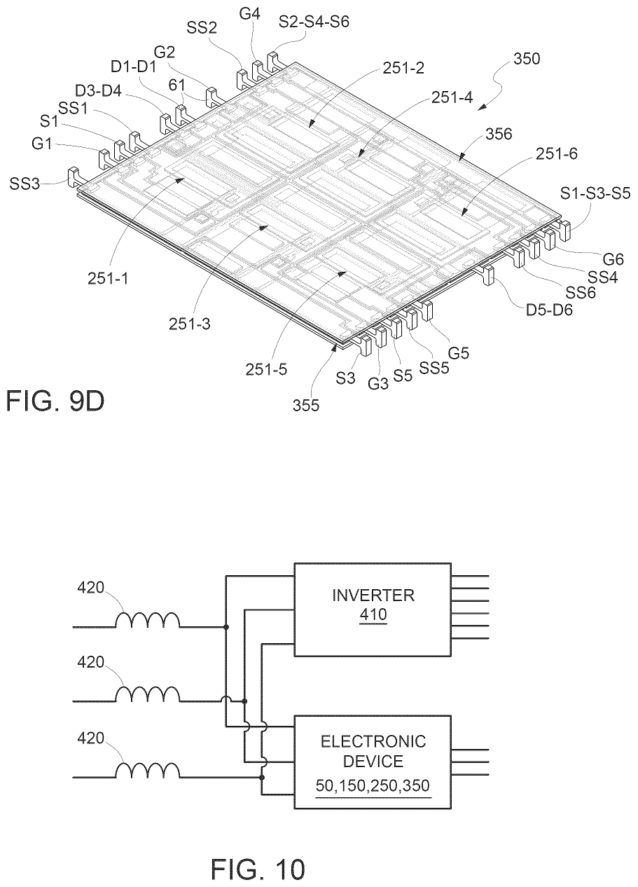

FIGS. 9A-9D refer to an electronic device 350 comprising, in a single packaged structure, the three horizontal branches 8A, 8B, 8C of the sub-circuits 5A, 5B, 5C in case the power devices 23, 24 are of the type shown in FIG. 3 or have a similar configuration of the external pads, i.e., all the external pads arranged on the same main surface 251A of the die (gate metallizations 42, source metallizations 43 and drain metallizations 44 of FIG. 3).

The electronic device 350 comprises six dice, the same as the electronic device 250 of FIGS. 8A-8D and therefore indicated by the same reference numbers (251, and, where useful to distinguish them, 251-1, 251-2, 251-3, 251-4, 251-5 and 251-6).

Furthermore, FIGS. 9A-9D refer to an electronic device 350 wherein the power devices 23, 24 are coupled in a drain-to-drain configuration.

In practice, the electronic device 350 of FIGS. 9A-9D has a general structure similar to the electronic device 250 of FIGS. 8A-8D, and therefore the components of FIGS. 9A-9D similar to those of FIGS. 8A-8D are indicated with reference numbers increased by 100.

The dice 251 of the electronic device 350 of FIGS. 9A-9D are arranged as described for the electronic device 250 of FIGS. 8A-8D, with all the metallizations 42-44 (FIGS. 3 and 9C) facing a same conductive layer (here indicated by 352) and belonging here to the upper substrate element (here indicated by 356), shown in detail in FIG. 9B.

Furthermore, the dice 251 are mounted with the lower surface 35B of FIG. 3 facing the lower substrate element (here indicated by 355) having the leads 61 attached thereto.

In particular, the electronic device 350 forms drain and source connection paths similar to those of the electronic device 150 of FIGS. 6A-6D and comprising three separate source paths S1, S3 and S5 of the first, third and fifth dice 251-1, 251-3 and 251-5; source paths S2, S4 and S6 of the second, fourth and sixth dice 251-2, 251-4 and 251-6 coupled and forming a common source path S2-S4-S6; and drain paths paired two by two and forming three paired-drain paths D1-D2, D3-D4 and D5-D6.

In FIG. 9A, therefore, the upper substrate element 356 forms three separate source islands 359′ for the first power devices 23 of the sub-circuits 5A, 5B, 5C of FIG. 1 (separate source islands 359′ forming the separate source paths S1, S3 and S5) and a common source island 359″ for the second power devices 24 of the sub-circuits 5A, 5B, 5C of FIG. 1 (common source island 359″ forming the common source path S4-S5-S6).

Furthermore, the upper substrate element 356 forms three paired-drain islands 358 between each first power device 23 and the respective second power device 24 of the sub-circuits 5A, 5B, 5C of FIG. 1 (paired-drain islands 358 forming the paired-drain paths D1-D2, D3-D4 and D5-D6).

FIG. 9A further shows a common source connection region 367″ (coupled to the common source island 359″), formed in the lower substrate element 355, and six separate source connection regions 367′, having the dice 251 bonded, for example soldered, thereto as better shown in FIG. 9C.

It should be noted that the three separate source connection regions 367′ relating to the power devices 24 of FIG. 1 (top of FIG. 9A) are shown distinct from the common source connection region 367″, but are electrically coupled thereto through the common source island 359″ in the upper substrate element 356 and, conceptually, might be incorporated by the common source connection region 367″.

A possible implementation of the shape and arrangement of the paired-drain islands 358 and the source islands 359′, 359″, the common source connection region 367″ and the separate source connection regions 367′ of FIG. 9A, of their external connection, as well as the shape and connections of the gate, source and drain metallizations 42-44 to form the power devices 23, 24 of FIG. 1 is visible in detail in FIGS. 9B-9D.

With particular reference to FIG. 9B, the patterned conductive layer 352 of the upper substrate element 356 forms, in addition to the three paired-drain islands 358, the separate source islands 259′ and the common source island 359″, six gate islands 362 intended to couple with the gate metallizations 42 of the dice 251.

Also in the embodiment shown in FIG. 9B, the contact between the gate islands 362 and the respective gate metallizations 42 (FIG. 9C), between the source islands 359′, 359″ and the respective source metallizations 43 (FIG. 9C), and between the drain islands 358 and the respective drain metallizations 44 (FIG. 9C) occurs through protrusions 363, 364, 382 protruding from the respective islands 362, 359′, 359″ and 358.

With particular reference to FIG. 9C, the patterned conductive layer 352 of the lower substrate element 355 forms, in addition to the common source connection region 367″ (coupled to the common source island 359″ of FIG. 9B), to the separate source connection regions 367′ (intended to couple to the dice 251-1, 251-3, 351-5 implementing the first power devices 23 of FIG. 1) and to the separate source connection regions 367′ (intended to couple to the dice 251-2, 251-4, 351-6 implementing the second power devices 24 of FIG. 1):
three drain connection regions 369, intended to couple to the paired-drain islands 358 of FIG. 8B;
six gate connection regions 366, each intended to couple to a respective gate island 362 of the upper substrate element 356 of FIG. 9B; and
six auxiliary source connection regions 390, having the dice 251 bonded thereto and coupled to the common source connection region 367″.

The auxiliary source connection regions 390 (coupled to respective leads 61 on connection paths indicated by SS1, SS2, SS3, SS4, SS5, SS6, also referred to as drive source leads) are useful in some applications as a reference of the gate voltage of the power devices 23, 24, in a per se known manner.

In particular, the auxiliary source connection regions 390 are connected independently of each other to respective leads of paths SS1, SS2, SS3, SS4, SS5 and SS6.

Furthermore, the auxiliary source connection regions 390 which the dice 251-2, 251-4 and 251-6 are bonded to, are electrically coupled to each other by the common source island 359″. Conversely, the auxiliary source connection regions 390, which the dice 251-1, 251-3 and 251-5 are bonded to, are connected independently of each other and to a respective separate source island 359′.

The patterned conductive layer 352 of the lower substrate element 355 also forms, in the embodiment shown in FIG. 9C, source protrusions 375, gate protrusions 376; and drain protrusions 378.

Here, the portions of the source islands 359 and 359″ are configured and arranged to vertically overlay the source metallizations 43 of the dice 251, the source connection regions 367′, 367″ and the auxiliary source connection regions 390.

More in particular, the source protrusions 364 are vertically overlaid to the source metallizations 43 of the dice 251 and the protrusions 375 of the source connection regions 367′, 367″ and of the auxiliary source connection regions 390.

Furthermore, each gate island 362 (and in particular, in the embodiment shown, each gate protrusion 363) is configured and arranged to vertically overly the gate metallization 42 of a respective die 251 and the protrusion 376 of a respective gate connection region 366.

Here, each drain island 358 (and in particular, in the embodiment shown, each drain protrusion 382) is configured and arranged to vertically overly the drain metallization 44 of a respective dice pair 251-1/251-2, 251-3/251-4, 251-5/251-6 and on the protrusion 378 of a respective drain connection region 369 of FIG. 9C.

In particular, the presence of the source protrusions 364 in the upper substrate element 356 and the source protrusions 375 on the source connection regions 367′, 367″ and on the auxiliary source connection regions 390 in the lower substrate element 355 allow here crossings of the gate connection regions 366 without electrical contact, as is also noted in FIG. 9D.

In FIG. 9C, for ease of understanding of the connections, the connection paths formed by the connections of FIG. 9A, and therefore the drain connection paths D1-D2, D3-D4, D5-D6, the gate connection paths G1, G2, G3, G4, G5, G6, and the source connection paths S1, S3, S5, S2-S4-S6 and SS1, SS2, SS3, SS4, SS5, SS6, are also indicated on the leads 61.

FIG. 9D shows the electronic device 350 after superimposing and coupling the upper substrate element 356 on/to the lower substrate element 356. In FIG. 9D, the upper substrate element 356 is shown in ghost, to highlight the connections between the connection regions and the respective islands, discussed above.

The electronic device 350, after packaging, for example by molding a package of insulating material, has an external shape similar to that of the packaged electronic device 70 of FIG. 5, except for the position of the leads 61.

FIG. 10 shows a three-phase PFC (Power Factor Corrector) power converter circuit 400 using the packaged electronic device 50, 150, 250, 350 described above and an inverter device 410 implemented as described in aforementioned Italian patent 102022000006563. The power converter circuit 400 may be easily assembled with inductive elements 420 and therefore in a simple and economical manner.

The described electronic device 50, 150, 250, 350 has numerous advantages. In fact, it is very compact, stackable, has a two-side cooling, and therefore excellent thermal performances. It has excellent insulation, reduction of inductive parasitic effects, may be coupled in parallel with other equal electronic devices, in drain-to-drain or source-to-source configuration for power devices of different technologies (MOSFETs of Si, SiC, GaN, IGBTs).

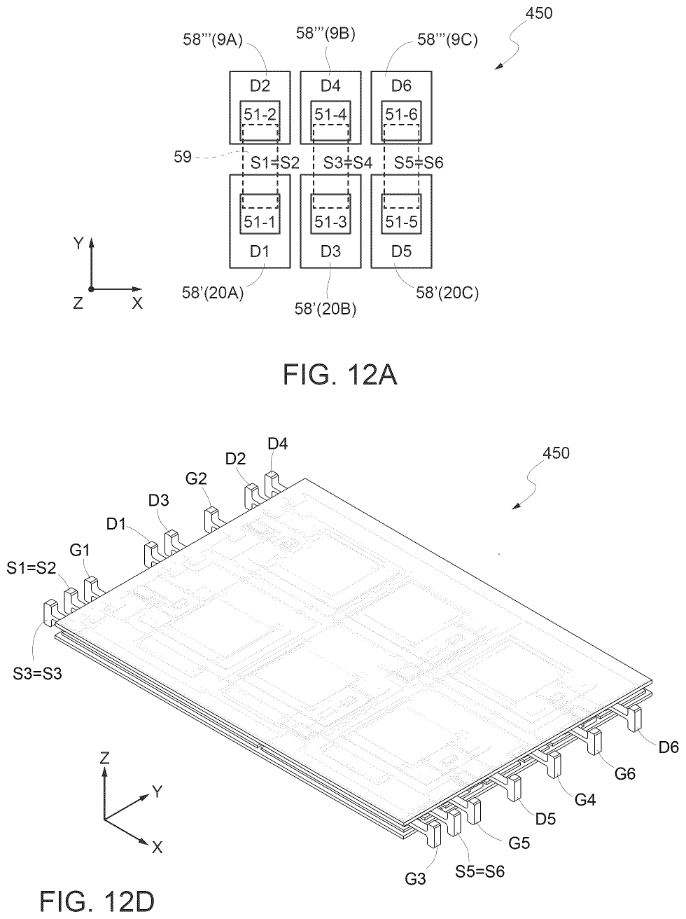

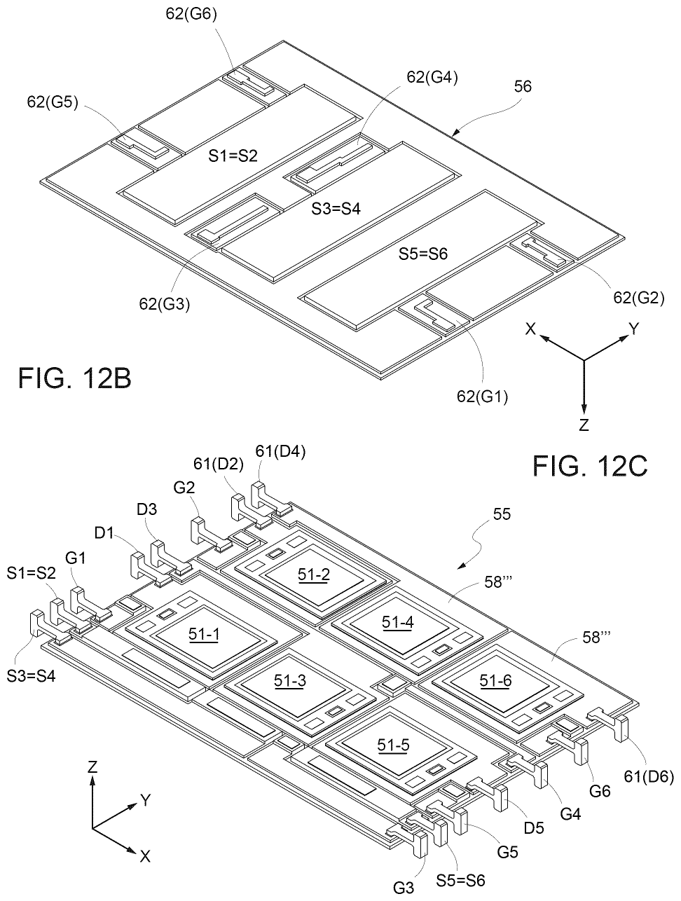

The three-phase PFC power converter circuit 400 may be coupled to external cooling systems, as for example shown in FIGS. 12 and 19-23 of the aforementioned Italian patent 102022000006563.

It may therefore be advantageously used in bidirectional electric vehicle (EV) charging stations and in AC-DC converters for storing domestic electrical energy.

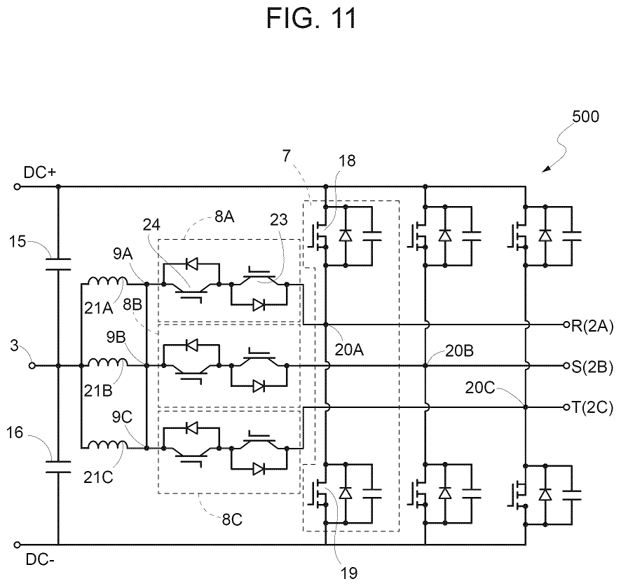

FIG. 11 shows a simplified diagram of an energy conversion unit 500 for AC-DC or DC-AC conversion, usable for example in bidirectional AC-DC electric vehicle (EV) charging stations, in bidirectional AC-DC on-board charging (OBD) systems and in bidirectional AC-DC power converters for accumulating domestic energy.

The energy conversion unit 500 of FIG. 11 is similar to the energy conversion unit 1 of FIG. 1; therefore common elements are designed by the same reference numbers and will not be described again.

The energy conversion unit 500 of FIG. 11 differs from the energy conversion unit 1 of FIG. 1 since, in energy conversion unit 500, an inductive element is arranged between each third connection node 9A, 9B, 9C and the second connection node 3. Specifically, a first inductive element 21A extends between the third connection node 9A of the first horizontal branch 8A and the second connection node 3; a second the inductive element 21B extends between the third connection node 9B of the second horizontal branch 8B and the second connection node 3; and a third inductive element 21C extends between the third connection node 9C of the third horizontal branch 8C and the second connection node 3.

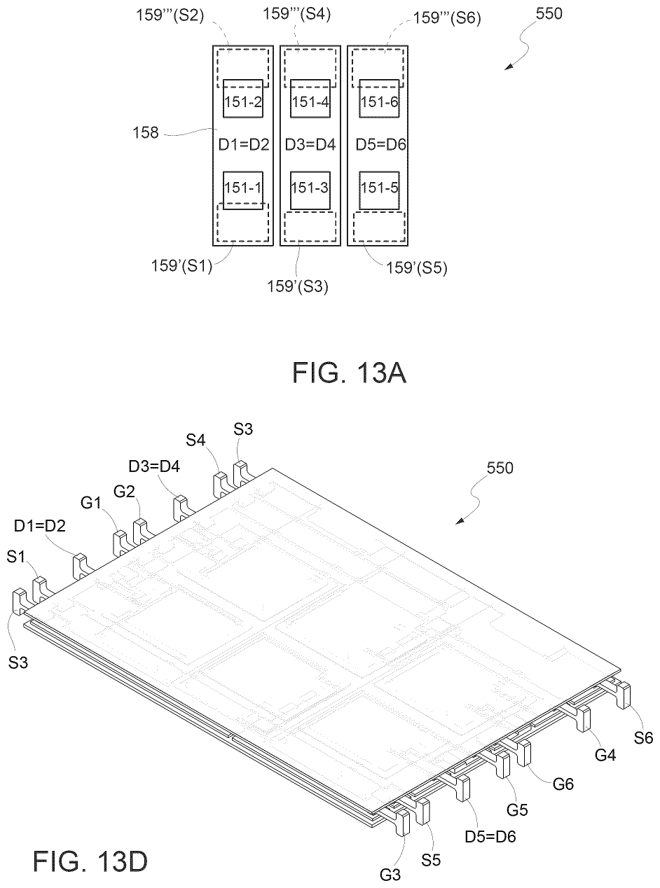

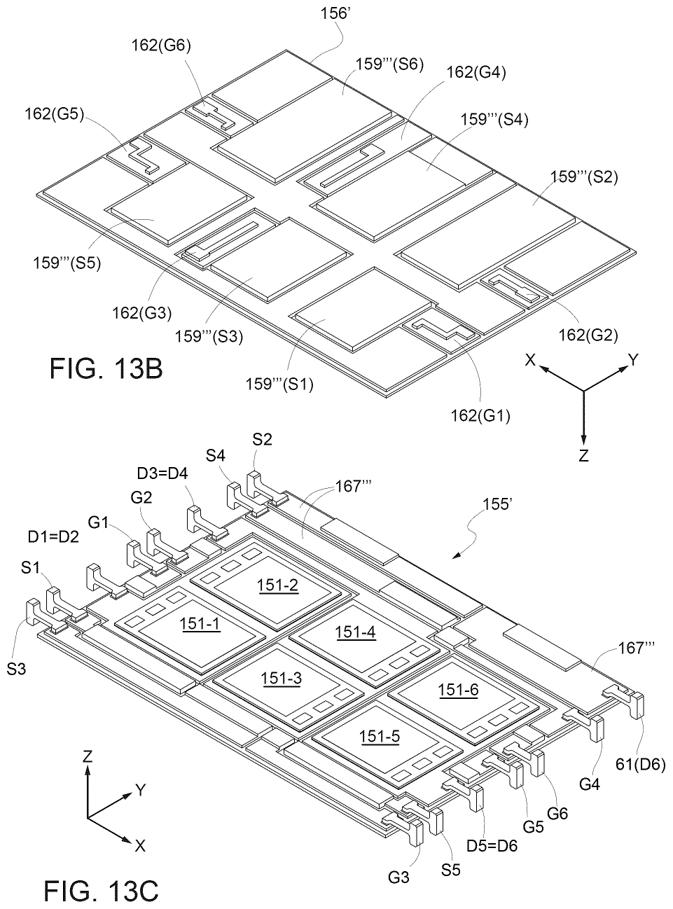

The horizontal branches 8A, 8B, 8C of the sub-circuits 5A, 5B, 5C of FIG. 11 may be implemented as discussed hereinbelow with reference to FIGS. 12A-13D.

In detail, FIGS. 12A-12D show an electronic device 450 comprising, in a single packaged structure, the three horizontal branches 8A, 8B, 8C of the sub-circuits 5A, 5B, 5C when the power devices 23, 24 are of the type shown in FIG. 2 or have a similar configuration of the external pads, i.e., a drain pad arranged on a main surface of the source and gate pads arranged on the opposite main surface and the power devices 23, 24 of FIG. 11 are coupled in a source-to-source configuration.

The electronic device 450 of FIGS. 12A-12D has a configuration similar to the electronic device 50 of FIGS. 4A-4D; therefore common elements are designed by the same reference numbers and will not be described again.

As represented schematically in FIG. 12A and visible from FIG. 12C, the electronic device 450 of FIGS. 12A-12D has three distinct drain paths D2, D4 and D6; therefore the lower substrate element (here indicated by 55′) forms three further separate drain islands, identified by reference numbers 58′″, for coupling the drain metallizations 27 of FIG. 2 to the second, the fourth and the sixth dice 51-2, 51-4 and 51-6 (i.e., to the dice 51 implementing the second power device 24 of the horizontal branches 8A, 8B, 8C of FIG. 11).

The three further separate drain islands 58′″ are coupled to the exterior of the electronic device 450 of FIGS. 12A-12D though respective pins 61 that here implement the distinct drain paths D2, D4, D6.

For the rest, the electronic device 450 of FIGS. 12A-12D is the same as the electronic device 50 of FIGS. 4A-4D, with the only peculiarity that the upper substrate element 56 is here shown to be turned around second axis Y of the Cartesian reference system XYZ when it is coupled to lower substrate element 55′.

FIGS. 13A-13D show an electronic device 550 comprising, in a single packaged structure, the three horizontal branches 8A, 8B, 8C of the sub-circuits 5A, 5B, 5C when the power devices 23, 24 are of the type shown in FIG. 2 or have a similar configuration of the external pads, i.e., a drain pad arranged on a main surface of the source and gate pads arranged on the opposite main surface and the power devices 23, 24 of FIG. 11 are coupled in a drain-to-drain configuration.

The electronic device 550 of FIGS. 13A-13D has a configuration similar to the electronic device 150 of FIGS. 6A-6D; therefore common elements are designed by the same reference numbers and will not be described again.

As represented schematically in FIG. 13A and visible from FIG. 13C, the electronic device 550 of FIGS. 13A-13D has three distinct source paths S2, S4 and S6; therefore the upper substrate element (here designed 156′) forms three further separate source islands, identified by reference numbers 159′″, for coupling the source metallizations 29 of FIG. 2 to the second, the fourth and the sixth dice 51-2, 51-4 and 51-6 (i.e., to the dice 51 implementing the second power device 24 of the horizontal branches 8A, 8B, 8C of FIG. 11).

In addition, the lower substrate element (here designed 155′), instead of the common source connection region 167″, has three further separate source connection regions 167′″ intended to couple to the three further separate source islands 159′″ in the upper substrate element 156′ (FIG. 13B).

For the rest, the electronic device 550 of FIGS. 13A-13D is the same as the electronic device 150 of FIGS. 6A-6D, with the only peculiarity that the upper substrate element 156′ is here shown to be turned around second axis Y of the Cartesian reference system XYZ when it is coupled to lower substrate element 155′.

Finally, it is clear that modifications and variations may be made to the electronic device 50, 150, 250, 350 described and illustrated herein without departing from the scope of the present disclosure.

For example, in the electronic device 50 of FIGS. 6A-6D, the common source island 159″ in the upper substrate element 156 might be formed by three distinct source islands, each configured to couple to a respective source metallization 29 of a respective die 51-2, 51-4 and 51-6, and they may be electrically coupled to form the source connection path S2-S4-S6 only through the common source connection region 167″.

Similarly, the electronic device 350 of FIGS. 9A-9D may be modified to have, instead of a single common source island 359″, three distinct source islands, each configured to be coupled to a respective source metallization 43 of a respective die 251-2, 251-4 and 251-6. Also in this case, the coupling between the source metallizations of the dice 251-2, 251-4 and 251-6 to form the source connection path S2-S4-S6 may occur through the common source connection region 367″.

An electronic device includes: a first substrate element (55; 156); a second substrate element (56; 155); and a first, a second, a third and a fourth die (51, 51-1, 51-2, 51-3, 51-4) of semiconductor material, each die integrating a power device (23, 24), the dice (51) having a first and a second main surface (51A, 51B), being arranged side-to-side and arranged between the first and the second substrate elements, each die having a first conduction terminal (29) and a control terminal (60) arranged on the first main surface (51A) and a second conduction terminal (27) arranged on the second main surface (51B), wherein the first and the second substrate elements (55, 56) includes each a multilayer including a first conductive layer (52; 152), a second conductive layer (54; 154) and an insulating layer (53; 153) arranged between the first and the second conductive layers, the first and the second dice (51-1, 51-2) form a first circuit (8A), the third and the fourth dice (51-3, 51-4) form a second circuit (8B), the power devices of the first circuit and the power devices of the second circuit being coupled in a same back-to-back configuration as the power devices (23, 24) of the first circuit (8A), the first circuit (8A) has a first intermediate terminal (6A), a first separate terminal (20A) and a first common terminal (9A), the first intermediate terminal (6A) coupled to one (29; 27) of the first (29) and the second (27) conduction terminals of the first die (51-1) and to one (29; 27) of the first (29) and the second (27) conduction terminals of the second die (51-2), the first separate terminal (20A) being coupled to the other (27; 29) of the first and the second conduction terminals of the first die (51-1), and the first common terminal (9A) being coupled to the other (27; 29) of the first and the second conduction terminals of the second die (51-2), the second circuit (8B) has a second intermediate terminal (6B), a second separate terminal (20B) and a second common terminal (9B), the second intermediate terminal (6B) coupled to one (29; 27) of the first (29) and the second (27) conduction terminals of the third die (51-3) and to one (29; 27) of the first (29) and the second (27) conduction terminals of the fourth die (51-4), the second separate terminal (20B) coupled to the other (27; 29) of the first and the second conduction terminals of the third die (51-3), and the second common terminal (9B) coupled to the other (27; 29) of the first and the second conduction terminals of the fourth die (51-4), the first conductive layer (52; 152) of the first substrate element (55; 156) is patterned to form: a first separate contact island (58′; 159′) coupled to the first separate terminal (20A); a second separate contact island (58′; 159′) coupled to the second separate terminal (20B); at least one common contact island (58″; 159″) coupled to the first and the second common terminals (9A, 9B), the first conductive layer (52; 152) of the second substrate element (56; 155) is patterned to form: at least one first intermediate contact island (59; 158; 180) coupled to the first intermediate terminal (6A), and at least one second intermediate contact island (59; 158; 180) coupled to the second intermediate terminal (6B).

The first die (51-1) is arranged side by side with the second die (51-2) along a first direction (Y) and may be arranged side by side with the third die (51-3) along a second direction (X), transversal to the first direction, the third die (51-3) may be arranged side by side with the fourth die (51-4) in the first direction.

The first conduction terminal (27) of the first, the second, the third and the fourth dice (51-1, 51-2, 51-3, 51-4) is a drain terminal and the second conduction terminal (29) of the first, the second, the third and the fourth dice may be a source terminal.

The first conductive layer (52) of the second substrate element (56) is patterned to further form a first, a second, a third and a fourth control island (62), the first conductive layer of the first substrate element (55) is patterned to form a first, a second, a third and a fourth control connection region (66), the first, the second, the third and the fourth control islands (62) facing and being electrically coupled respectively to the first, the second, the third and the fourth control connection regions (66), and the first, the second, the third and the fourth control connection regions (66) are coupled to respective external leads (61).

The first conductive layer (52) of the first substrate element (55) is patterned to form a first and a second intermediate connection region (67) facing and electrically coupled to the first and, respectively, the second intermediate contact island (59).

The first and the second intermediate connection regions (67) are coupled to respective external leads (61).

The first separate contact island (58′), the second separate contact island (58′) and the common contact island (58″) are coupled to respective external leads (61).

The first intermediate contact island (59) and the second intermediate contact island (59) have protrusions (64) for contacting respective first conduction terminals (29) of the first, the second, the third and the fourth dice.

The electronic device further include a fifth (51-5) and a sixth die (51-6) of semiconductor material, the fifth and the sixth dice integrating a respective power device (23, 24) and having a respective first and a respective second main surface (51A, 51B), the fifth and the sixth dice arranged side by side with each other and with the first, the second, the third and the fourth dice (51-1, 51-2, 51-3, 51-4) and arranged between the first and the second substrate elements (56; 155), the fifth and the sixth dice having a first conduction terminal (29) and a control terminal (60) arranged on the respective first main surface (51A) and a second conduction terminal (27) arranged on the respective second main surface (51B), the fifth and the sixth dice forming a third circuit (8C), with the power devices of the third circuit coupled in a same back-to-back configuration as the first and the second circuits (8A, 8B), the third circuit (8C) having a third intermediate terminal (6C), a third separate terminal (20C) and a third common terminal (9C), the third intermediate terminal (6C) coupled to one (29; 27) of the first (29) and the second (27) conduction terminals of the fifth die (51-5) and to one (29; 27) of the first (29) and the second (27) conduction terminals of the sixth die (51-6), the third separate terminal (20C) coupled to the other (27; 29) of the first and the second conduction terminals of the fifth die (51-5) and the third common terminal (9C) coupled to the other (27; 29) of the first and the second conduction terminals of the sixth die (51-6), wherein the first conductive layer (52) of the first substrate element (55; 156) is further patterned to form a third separate contact island (58′; 159′) coupled to the third separate terminal (20C); the common contact island (58″; 159″) of the first substrate element (55; 156) further coupled to the third common terminal (9C), wherein the first conductive layer (52) of the second substrate element (56; 155) is further patterned to form a third intermediate contact island (59; 158) coupled to the third intermediate terminal (6C).

The first conduction terminal (29) of the first, the second, the third and the fourth dice (51-1, 51-2, 51-3,51-4) is a source terminal and the second conduction terminal (27) of the first, the second, the third and the fourth dice is a drain terminal.

The first conductive layer (152) of the first substrate element (155) is patterned to further form a first, a second, a third and a fourth control island (162), the first conductive layer of the second substrate element (155) is patterned to form a first, a second, a third and a fourth control connection region (166), the first, the second, the third and the fourth control islands (162) facing and being electrically coupled respectively to the first, the second, the third and the fourth control connection regions (166), and the first, the second, the third and the fourth control connection regions (166) are coupled to respective external leads (61).

An electronic device includes: a first substrate element (255; 355); a second substrate element (256; 356); and a first, a second, a third and a fourth die (251, 251-1, 252-2, 251-3, 251-4) of semiconductor material, each die integrating a power device (23, 24), the dice (251) having a first and a second main surface (251A, 35B), being arranged side by side to each other and interposed between the first and the second substrate elements, each die having a first conduction terminal (43), a second conduction terminal (44) and a control terminal (42) arranged on the first main surface (251A), each die coupled to the first substrate element (255; 355) with a respective second main surface (35B), wherein the first and the second substrate elements (255, 256; 355, 356) each includes a multilayer including a first conductive layer (252; 352), a second conductive layer (254; 254), and an insulating layer (253; 253) arranged between the first and the second conductive layers, the first and the second dice (51-1, 51-2) form a first circuit (8A), the third and the fourth dice (51-3, 51-4) form a second circuit (8B), the power devices of the first circuit and the power devices (23, 24) of the second circuit (8B) coupled in a same back-to-back configuration as the power devices (23, 24) of the first circuit (8A), the first circuit has a first intermediate terminal (6A), a first separate terminal (20A) and a first common terminal (9A), the first intermediate terminal (6A) coupled to one (43; 44) of the first (43) and the second (44) conduction terminals of the first die (251-1) and to one (43; 44) of the first (43) and the second (44) conduction terminals of the second die (251-2), the first separate terminal (20A) coupled to the other (44; 43) of the first and the second conduction terminals of the third die and the first common terminal coupled to the other of the first and the second conduction terminals of the second die (251-2), the second circuit (8B) has a second intermediate terminal (6B), a second separate terminal (20B) and a second common terminal (9B), the second intermediate terminal (6B) coupled to one (43; 44) of the first (43) and the second (44) conduction terminals of the third die (251-3) and to one (43; 44) of the first (43) and the second (44) conduction terminals of the fourth die (251-4), the second separate terminal (20B) coupled to the other (44; 43) of the first and the second conduction terminals of the third die (251-3), and the second common terminal (9B) coupled to the other (44; 43) of the first and the second conduction terminals of the fourth die (251-4), the first conductive layer of the second substrate element (256; 356) is patterned to form: a first separate contact island (258′; 359′) coupled to the first separate terminal (20A); a second separate contact island (258′; 359′) coupled to the second separate terminal (20B); a first intermediate contact island (259; 358) coupled to the first intermediate terminal (6A), a second intermediate contact island (259; 358) coupled to the second intermediate terminal (6B) and at least a third common contact island (258″, 359″) coupled to the first and the second common terminals (9A, 9B).

The first conductive layer (252, 352) of the first substrate element (255; 355) forms: a first separate connection region (269′; 367′) coupled to the first separate contact island (258′; 359′); a second separate connection region (269′; 367′) coupled to the second separate contact island (258′; 359′); a first intermediate connection region (267; 358) coupled to the first intermediate contact island (259; 358), a second intermediate connection region (267; 358) coupled to the second intermediate contact island (259; 358), and a third common connection region (269; 367′, 375) coupled to the third common contact island (258″, 359″).

The various embodiments described above can be combined to provide further embodiments. Other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. An electronic device comprising:
a first substrate element;
a second substrate element; and
a first, a second, a third, and a fourth die, each die integrating a power device, the dice having a first and a second main surface, being arranged side by side and arranged between the first and the second substrate elements, each die having a first conduction terminal and a control terminal arranged on the first main surface and a second conduction terminal arranged on the second main surface,
wherein the first and the second substrate elements comprise each a multilayer including a first conductive layer, a second conductive layer and an insulating layer arranged between the first and the second conductive layers,
wherein the first and the second dice form a first circuit, the third and the fourth dice form a second circuit, the power devices of the first circuit and the power devices of the second circuit being coupled in a same back-to-back configuration as the power devices of the first circuit,
wherein the first circuit has a first intermediate terminal, a first separate terminal and a first further terminal, the first intermediate terminal coupled to one of the first and the second conduction terminals of the first die and to one of the first and the second conduction terminals of the second die, the first separate terminal being coupled to the other of the first and the second conduction terminals of the first die, and the first further terminal being coupled to the other of the first and the second conduction terminals of the second die,
wherein the second circuit has a second intermediate terminal, a second separate terminal and a second further terminal, the second intermediate terminal coupled to one of the first and the second conduction terminals of the third die and to one of the first and the second conduction terminals of the fourth die, the second separate terminal coupled to the other of the first and the second conduction terminals of the third die, and the second further terminal coupled to the other of the first and the second conduction terminals of the fourth die,
wherein the first conductive layer of the first substrate element is patterned to include:
a first separate contact island coupled to the first separate terminal;
a second separate contact island coupled to the second separate terminal;
at least one further contact island coupled to the first further terminal,
the first conductive layer of the second substrate element is patterned to include:
at least one first intermediate contact island coupled to the first intermediate terminal, and
at least one second intermediate contact island coupled to the second intermediate terminal.

2. The electronic device according to claim 1, wherein the first further terminal of the first circuit is a first common terminal, the second further terminal of the second circuit is a second common terminal and the further contact island is a common contact island coupled to the second further terminal.

3. The electronic device according to claim 1, wherein the first die is arranged side by side with the second die along a first direction and is arranged side by side with the third die along a second direction, transversal to the first direction, the third die is arranged side by side with the fourth die in the first direction.

4. The electronic device according to claim 2, wherein the first conduction terminal of the first, the second, the third and the fourth dice is a drain terminal and the second conduction terminal of the first, the second, the third, and the fourth dice is a source terminal.

5. The electronic device according to claim 4, wherein:
the first conductive layer of the second substrate element is patterned to further include a first, a second, a third and a fourth control island,
the first conductive layer of the first substrate element is patterned to include a first, a second, a third, and a fourth control connection region,
the first, the second, the third, and the fourth control islands facing and being electrically coupled respectively to the first, the second, the third, and the fourth control connection regions, and
the first, the second, the third, and the fourth control connection regions are coupled to respective external leads.

6. The electronic device according to claim 4, wherein the first conductive layer of the first substrate element is patterned to include a first and a second intermediate connection region facing and electrically coupled to the first and, respectively, the second intermediate contact island.

7. The electronic device according to claim 6, wherein the first and the second intermediate connection regions are coupled to respective external leads.

8. The electronic device according to claim 4, wherein the first separate contact island, the second separate contact island and the common contact island are coupled to respective external leads.

9. The electronic device according to claim 4, wherein the first intermediate contact island and the second intermediate contact island have protrusions for contacting respective first conduction terminals of the first, the second, the third, and the fourth dice.

10. The electronic device according to claim 2, further comprising a fifth and a sixth die,
the fifth and the sixth dice integrating a respective power device and having a respective first and a respective second main surface, the fifth and the sixth dice arranged side by side with each other and with the first, the second, the third and the fourth dice and arranged between the first and the second substrate elements, the fifth and the sixth dice having a first conduction terminal and a control terminal arranged on the respective first main surface and a second conduction terminal arranged on the respective second main surface,
the fifth and the sixth dice including a third circuit, with the power devices of the third circuit coupled in a same back-to-back configuration as the first and the second circuits,
the third circuit having a third intermediate terminal, a third separate terminal and a third common terminal, the third intermediate terminal coupled to one of the first and the second conduction terminals of the fifth die and to one of the first and the second conduction terminals of the sixth die, the third separate terminal coupled to the other of the first and the second conduction terminals of the fifth die and the third common terminal coupled to the other of the first and the second conduction terminals of the sixth die,
wherein the first conductive layer of the first substrate element is further patterned to include a third separate contact island coupled to the third separate terminal;
the common contact island of the first substrate element further coupled to the third common terminal,
wherein the first conductive layer of the second substrate element is further patterned to include a third intermediate contact island coupled to the third intermediate terminal.

11. The electronic device according to claim 1, wherein the first conduction terminal of the first, the second, the third, and the fourth dice is a source terminal and the second conduction terminal of the first, the second, the third, and the fourth dice is a drain terminal.

12. The electronic device according to claim 11, wherein:
the first conductive layer of the first substrate element is patterned to further include a first, a second, a third and a fourth control island,
the first conductive layer of the second substrate element is patterned to include a first, a second, a third, and a fourth control connection region,
the first, the second, the third, and the fourth control islands facing and being electrically coupled respectively to the first, the second, the third, and the fourth control connection regions, and
the first, the second, the third, and the fourth control connection regions are coupled to respective external leads.

13. An electronic device comprising:
a first substrate element;
a second substrate element; and
a first, a second, a third, and a fourth die, each die integrating a power device, the dice having a first and a second main surface, being arranged side by side to each other and interposed between the first and the second substrate elements, each die having a first conduction terminal, a second conduction terminal, and a control terminal arranged on the first main surface, each die coupled to the first substrate element with a respective second main surface,
wherein the first and the second substrate elements each comprise a multilayer including a first conductive layer, a second conductive layer, and an insulating layer arranged between the first and the second conductive layers,
wherein the first and the second dice form a first circuit, the third and the fourth dice form a second circuit, the power devices of the first circuit and the power devices of the second circuit coupled in a same back-to-back configuration as the power devices of the first circuit,
wherein the first circuit has a first intermediate terminal, a first separate terminal and a first common terminal, the first intermediate terminal coupled to one of the first and the second conduction terminals of the first die and to one of the first and the second conduction terminals of the second die, the first separate terminal coupled to the other of the first and the second conduction terminals of the third die and the first common terminal coupled to the other of the first and the second conduction terminals of the second die,
wherein the second circuit has a second intermediate terminal, a second separate terminal and a second common terminal, the second intermediate terminal coupled to one of the first and the second conduction terminals of the third die and to one of the first and the second conduction terminals of the fourth die, the second separate terminal coupled to the other of the first and the second conduction terminals of the third die, and the second common terminal coupled to the other of the first and the second conduction terminals of the fourth die,
the first conductive layer of the second substrate element is patterned to include:
a first separate contact island coupled to the first separate terminal;
a second separate contact island coupled to the second separate terminal;
a first intermediate contact island coupled to the first intermediate terminal,
a second intermediate contact island coupled to the second intermediate terminal and
at least a third common contact island coupled to the first and the second common terminals.

14. The electronic device according to claim 13, wherein the first conductive layer of the first substrate element includes:
a first separate connection region coupled to the first separate contact island;
a second separate connection region coupled to the second separate contact island;
a first intermediate connection region coupled to the first intermediate contact island,
a second intermediate connection region coupled to the second intermediate contact island, and
a third common connection region coupled to the third common contact island.

15. An electronic device comprising:
a first, a second, a third, and a fourth die, each die integrating a power device, the dice having a first and a second main surface, each die having a first conduction terminal and a control terminal arranged on the first main surface and a second conduction terminal arranged on the second main surface;
a first conductive layer, a second conductive layer, and an insulating layer between the first and the second conductive layers;
a first circuit on the first and the second dice, the first circuit having a first intermediate terminal, a first separate terminal, and a first common terminal, the first intermediate terminal coupled to one of the first and the second conduction terminals of the first die and to one of the first and the second conduction terminals of the second die, the first separate terminal being coupled to the other of the first and the second conduction terminals of the first die, and the first common terminal being coupled to the other of the first and the second conduction terminals of the second die;
a second circuit on the third and the fourth dice, the power devices of the first circuit and the power devices of the second circuit being coupled in a same back-to-back configuration as the power devices of the first circuit, the second circuit having a second intermediate terminal, a second separate terminal, and a second common terminal, the second intermediate terminal coupled to one of the first and the second conduction terminals of the third die and to one of the first and the second conduction terminals of the fourth die, the second separate terminal coupled to the other of the first and the second conduction terminals of the third die, and the second common terminal coupled to the other of the first and the second conduction terminals of the fourth die;
a first separate contact island coupled to the first separate terminal;
a second separate contact island coupled to the second separate terminal;
at least one common contact island coupled to the first and the second common terminals;
at least one first intermediate contact island coupled to the first intermediate terminal; and
at least one second intermediate contact island coupled to the second intermediate terminal.

16. The electronic device according to claim 15, wherein the first die is arranged side by side with the second die along a first direction and is arranged side by side with the third die along a second direction, transversal to the first direction, the third die is arranged side by side with the fourth die in the first direction.

17. The electronic device according to claim 14, wherein either:
the first conduction terminal of the first, the second, the third and the fourth dice is a drain terminal and the second conduction terminal of the first, the second, the third, and the fourth dice is a source terminal; or
wherein the first conduction terminal of the first, the second, the third, and the fourth dice is a source terminal and the second conduction terminal of the first, the second, the third, and the fourth dice is a drain terminal.

18. The electronic device according to claim 17, wherein:
the first conductive layer of the second substrate element is patterned to further include a first, a second, a third, and a fourth control island,
the first conductive layer of the first substrate element is patterned to include a first, a second, a third, and a fourth control connection region,
the first, the second, the third, and the fourth control islands facing and being coupled respectively to the first, the second, the third, and the fourth control connection regions, and
the first, the second, the third, and the fourth control connection regions are coupled to respective external leads.

19. The electronic device according to claim 17, wherein the first separate contact island, the second separate contact island and the common contact island are coupled to respective external leads.

20. The electronic device according to claim 17, wherein the first intermediate contact island and the second intermediate contact island have protrusions for contacting respective first conduction terminals of the first, the second, the third, and the fourth dice.

21. The electronic device according to claim 15, further comprising a fifth and a sixth die,
the fifth and the sixth dice integrating a respective power device and having a respective first and a respective second main surface, the fifth and the sixth dice arranged side by side with each other and with the first, the second, the third and the fourth dice, the fifth and the sixth dice having a first conduction terminal and a control terminal arranged on the respective first main surface and a second conduction terminal arranged on the respective second main surface,
the fifth and the sixth dice including a third circuit, with the power devices of the third circuit coupled in a same back-to-back configuration as the first and the second circuits,
the third circuit having a third intermediate terminal, a third separate terminal and a third common terminal, the third intermediate terminal coupled to one of the first and the second conduction terminals of the fifth die and to one of the first and the second conduction terminals of the sixth die, the third separate terminal coupled to the other of the first and the second conduction terminals of the fifth die and the third common terminal coupled to the other of the first and the second conduction terminals of the sixth die.
